(19) United States
(12) Patent Application Publication
(10) Pub. No.: US 2025/0338492 A1
(43) Pub. Date: Oct. 30, 2025

(54) SEMICONDUCTOR DEVICE INCLUDING VERTICAL ACTIVE PATTERN

(71) Applicant: Samsung Electronics Co., Ltd., Suwon-si (KR)

(72) Inventors: Taehyuk KIM, Suwon-si (KR); Taekyong KIM, Suwon-si (KR); Hyunah ROH, Suwon-si (KR)

(73) Assignee: Samsung Electronics Co., Ltd., Suwon-si (KR)

(21) Appl. No.: 19/026,983

(22) Filed: Jan. 17, 2025

(30) Foreign Application Priority Data
Apr. 29, 2024 (KR) 10-2024-0056942

(51) Int. Cl. H10B 12/00

(52) U.S. Cl. CPC H10B 12/50; H10B 12/09; H10B 12/315

(57) ABSTRACT

A semiconductor device includes a memory region and a peripheral region. The memory region includes a cell vertical active pattern; a cell upper source/drain pattern and a cell contact plug sequentially stacked on the cell vertical active pattern; and a cell isolation pattern on side surfaces of the cell upper source/drain pattern and the cell contact plug. The peripheral region includes a peripheral vertical active pattern; a peripheral upper source/drain pattern and a peripheral contact plug sequentially stacked on the peripheral vertical active pattern; a peripheral isolation pattern on side surfaces of the peripheral upper source/drain pattern and the peripheral contact plug; and an upper wiring on the peripheral contact plug and the peripheral isolation pattern. The cell upper source/drain pattern includes a first cell upper source/drain pattern and a second cell upper source/drain pattern stacked in order.

### CROSS-REFERENCE TO RELATED APPLICATION(S)

This application claims benefit of and priority to Korean Patent Application No. 10-2024-0056942 filed on Apr. 29, 2024 in the Korean Intellectual Property Office, the disclosure of which is incorporated herein by reference in its entirety.

### BACKGROUND

Some example embodiments of the present disclosure relate to a semiconductor devices and/or methods of manufacturing the same.

Research to reduce the size of elements included in a semiconductor device and to improve performance thereof has been conducted. For example, in a DRAM, research to reliably and stably form elements having reduced sizes has been conducted, but as the sizes of the elements have been reduced, dispersion properties of a semiconductor device may be deteriorated.

### SUMMARY

Some example embodiments of the present disclosure are to provide semiconductor devices which may increase integration density and may improve performance.

Some example embodiments of the present disclosure is to provide methods of manufacturing the semiconductor devices.

According to some example embodiments, a semiconductor device includes a memory region and a peripheral region, the memory region including a cell vertical active pattern; a cell gate electrode having a side surface facing a side surface of the cell vertical active pattern; a cell upper source/drain pattern and a cell contact plug on the cell vertical active pattern and stacked in order; a cell isolation pattern on side surfaces of the cell upper source/drain pattern and the cell contact plug; and a data storage structure on the cell contact plug and the cell isolation pattern, the peripheral region including a peripheral vertical active pattern; a peripheral gate electrode having a side surface facing a side surface of the peripheral vertical active pattern; a peripheral upper source/drain pattern and a peripheral contact plug on the peripheral vertical active pattern and stacked in order; a peripheral isolation pattern on a side surface of the peripheral upper source/drain pattern and a side surface of the peripheral contact plug; and an upper wiring on the peripheral contact plug and the peripheral isolation pattern, wherein the cell upper source/drain pattern includes a first cell upper source/drain pattern and a second cell upper source/drain pattern stacked in order, and wherein the peripheral upper source/drain pattern includes a first peripheral upper source/drain pattern and a second peripheral upper source/drain pattern stacked in order.

According to some example embodiments, a semiconductor device includes a cell vertical active pattern and a peripheral vertical active pattern spaced apart from each other; a cell upper source/drain pattern and a cell contact plug stacked in order on the cell vertical active pattern and self-aligned; a peripheral upper source/drain pattern and a peripheral contact plug stacked in order on the peripheral vertical active pattern and self-aligned; a cell isolation pattern on a side surface of the cell upper source/drain pattern and a side surface of the cell contact plug; a peripheral isolation pattern on a side surface of the peripheral upper source/drain pattern and a side surface of the peripheral contact plug; an upper wiring connected to the peripheral contact plug and on the peripheral contact plug; an insulating liner on the cell contact plug, the cell isolation pattern and the upper wiring; and a data storage structure including a first electrode connected to the cell contact plug, the first electrode penetrating the insulating liner and extending upwardly, a dielectric layer on the first electrode, and a second electrode on the dielectric layer, wherein the insulating liner includes a first portion on an upper surface of the cell isolation pattern and a second portion on an upper surface of the upper wiring, and wherein the second portion of the insulating liner is on a level higher than a level of the first portion of the insulating liner.

According to some example embodiments, a semiconductor device includes a first structure including a memory region and a peripheral region; and a second structure vertically overlapping the first structure and including a peripheral circuit, wherein the memory region includes a cell vertical active pattern; a cell gate electrode having a side surface facing a side surface of the cell vertical active pattern; a cell upper source/drain pattern and a cell contact plug on the cell vertical active pattern and stacked in order; a cell isolation pattern on side surfaces of the cell upper source/drain pattern and the cell contact plug; and a data storage structure on the cell contact plug and the cell isolation pattern, wherein the peripheral region includes a first peripheral vertical active pattern; a first peripheral gate electrode having a side surface facing a side surface of the first peripheral vertical active pattern; a first peripheral upper source/drain pattern and a first peripheral contact plug on the first peripheral vertical active pattern and stacked in order; a peripheral isolation pattern on a side surface of the first peripheral upper source/drain pattern and a side surface of the first peripheral contact plug; and a first upper wiring on the first peripheral contact plug and the peripheral isolation pattern, wherein the cell upper source/drain pattern includes a first cell upper source/drain pattern and a second cell upper source/drain pattern stacked in order, wherein the first peripheral upper source/drain pattern includes a first-1 peripheral upper source/drain pattern and a first-2 peripheral upper source/drain pattern stacked in order, wherein the memory region and the peripheral region further include an insulating liner on the cell contact plug, the cell isolation pattern, and the first upper wiring, and wherein the peripheral circuit includes a first lower transistor vertically overlapping the memory region and a second lower transistor vertically overlapping the peripheral region.

### BRIEF DESCRIPTION OF DRAWINGS

Other aspects, features, and advantages in the example embodiments will be more clearly understood from the following detailed description, taken in combination with the accompanying drawings, in which:

FIG. 1 is a perspective diagram illustrating a semiconductor device according to some example embodiments of the present disclosure;

FIG. 2 is a circuit diagram illustrating a memory region of a semiconductor device according to some example embodiments of the present disclosure;

FIGS. 3, 4, 5A, 5B and 6 are diagrams illustrating an example of a semiconductor device according to some example embodiments of the present disclosure;

FIG. 7 is an enlarged diagram illustrating a portion of an example of a semiconductor device according to some example embodiments of the present disclosure;

FIGS. 8A and 8B are diagrams illustrating an example of a semiconductor device according to some example embodiments of the present disclosure;

FIGS. 9A and 9B are diagrams illustrating an example of a semiconductor device according to some example embodiments of the present disclosure;

FIGS. 10A and 10B are diagrams illustrating an example of a semiconductor device according to some example embodiments of the present disclosure;

FIGS. 11A and 11B are diagrams illustrating an example of a semiconductor device according to some example embodiments of the present disclosure;

FIGS. 12, 13A and 13B are diagrams illustrating an example of a semiconductor device according to some example embodiments of the present disclosure;

FIG. 14A is a cross-sectional diagram illustrating an example of a semiconductor device according to some example embodiments of the present disclosure;

FIG. 14B is a cross-sectional diagram illustrating an example of a semiconductor device according to some example embodiments of the present disclosure;

FIG. 15A is a cross-sectional diagram illustrating an example of a semiconductor device according to some example embodiments of the present disclosure;

FIG. 15B is a cross-sectional diagram illustrating an example of a semiconductor device according to some example embodiments of the present disclosure;

FIG. 16 is a cross-sectional diagram illustrating an example of a semiconductor device according to some example embodiments of the present disclosure;

FIG. 17 is a cross-sectional diagram illustrating an example of a semiconductor device according to some example embodiments of the present disclosure; and

FIGS. 18 to 37 are cross-sectional diagrams illustrating an example of a method of manufacturing a semiconductor device according to some example embodiments of the present disclosure.

### DETAILED DESCRIPTION

Hereinafter, terms such as “upper”, “middle”, “lower” and the like may be replaced with other terms, such as “first”, “second”, “third” and the like to describe the elements of the specification. Terms such as “first”, “second”, “third” and the like may be used to describe various elements, but the elements are not limited by the terms, e.g., the terms are not intended to imply or require sequential inclusion, and a “first element” may be referred to as a “second element”.

It will be understood that elements and/or properties thereof (e.g., structures, surfaces, directions, or the like), which may be referred to as being “perpendicular,” “parallel,” “coplanar,” or the like with regard to other elements and/or properties thereof (e.g., structures, surfaces, directions, or the like) may be “perpendicular,” “parallel,” “coplanar,” or the like or may be “substantially perpendicular,” “substantially parallel,” “substantially coplanar,” respectively, with regard to the other elements and/or properties thereof. Elements and/or properties thereof (e.g., structures, surfaces, directions, or the like) that are “substantially perpendicular” with regard to other elements and/or properties thereof will be understood to be “perpendicular” with regard to the other elements and/or properties thereof within manufacturing tolerances and/or material tolerances and/or have a deviation in magnitude and/or angle from “perpendicular,” or the like with regard to the other elements and/or properties thereof that is equal to or less than 10% (e.g., a. tolerance of ±10%).

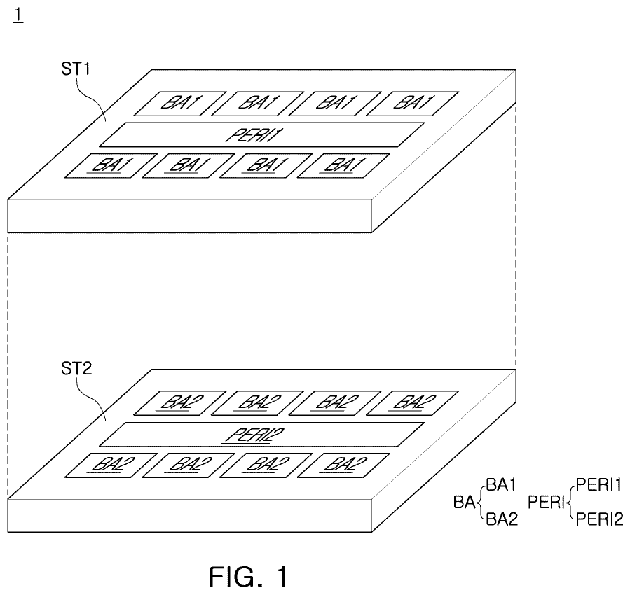

Hereinafter, a semiconductor device according to some example embodiments will be described. FIG. 1 is a perspective diagram illustrating a semiconductor device according to some example embodiments.

Referring to FIG. 1, a semiconductor device 1 according to some example embodiments may include a first structure ST1 and a second structure ST2 vertically overlapping the first structure ST1. The second structure ST2 may be disposed below the first structure ST1.

In some example embodiments, the first structure ST1 may be configured as a first chip structure including a memory region and a peripheral region, and the second structure ST2 may be configured as a second chip structure including a second peripheral circuit. The first structure ST1 and the second structure ST2 may be bonded to each other through a bonding process such as a wafer bonding process. Accordingly, the first structure ST1 may be in contact with and bonded to the second structure ST2.

The semiconductor device 1 may include a plurality of banks BA and an external peripheral region PERI.

The external peripheral region PERI may include a peripheral region PERI1 in the first structure ST1 and a second peripheral region PERI2 in the second structure ST2. The external peripheral region PERI may be configured as a peripheral region in which peripheral circuits for input and output of data or commands, or input of power/ground are disposed.

Each of the plurality of banks BA may include a first bank region BA1 in the first structure ST1 and a second bank region BA2 in the second structure ST2.

The first bank region BA1 in the first structure ST1 may include memory cells. The second bank region BA2 in the second structure ST2 may include peripheral circuits such as a sense amplifier and a sub-wordline driver.

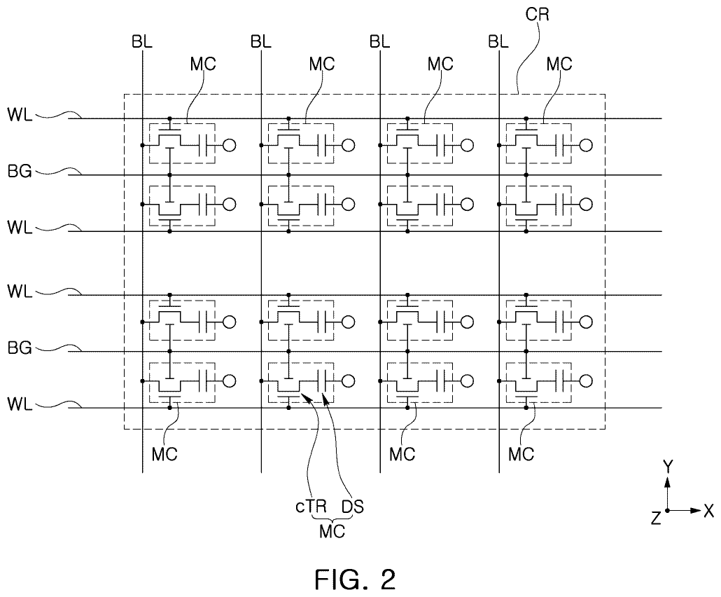

In the description below, a circuit in the memory region of the first structure ST1 will be described with reference to FIG. 2. FIG. 2 is a circuit diagram illustrating a memory region of a semiconductor device according to some example embodiments.

Referring to FIG. 2, the memory region CR may include memory cells MC. The memory region CR may include memory cells MC arranged in the first direction X and the second direction Y, wordlines WL connected to the memory cells MC and extending in the first direction X, and bit lines BL connected to the memory cells MC and extending in the second direction Y. The first direction X and the second direction Y may be perpendicular to each other.

The wordlines WL may cross the memory region CR in the first direction X. The bit lines BL may cross the memory region CR in the second direction Y.

Each of the memory cells MC may include a data storage structure DS working as data storage and a cell transistor cTR electrically connected to the data storage structure DS. In a memory such as a DRAM, the data storage structure DS may be configured as a cell capacitor which may store data.

The memory region CR may further include back gate lines BG. Each of the back gate lines BG may be disposed between a pair of wordlines WL adjacent to each other in the second direction Y among the wordlines WL. Each of the back gate lines BG may be disposed between vertical channel regions of the cell transistors cTR.

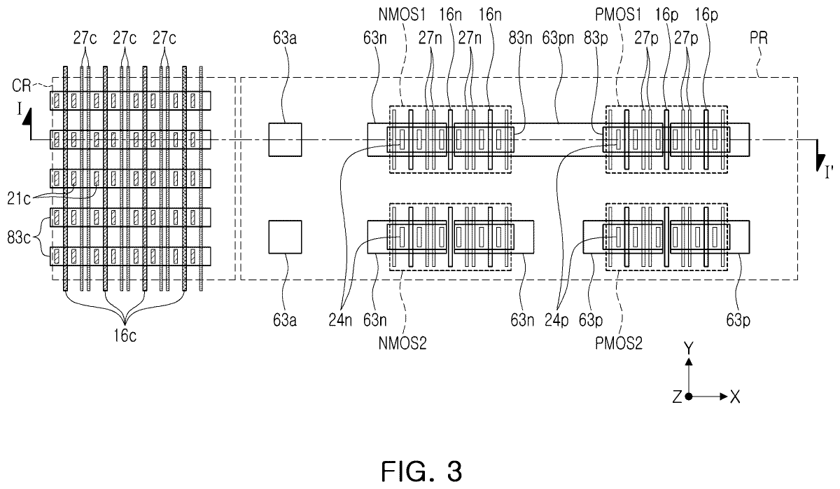

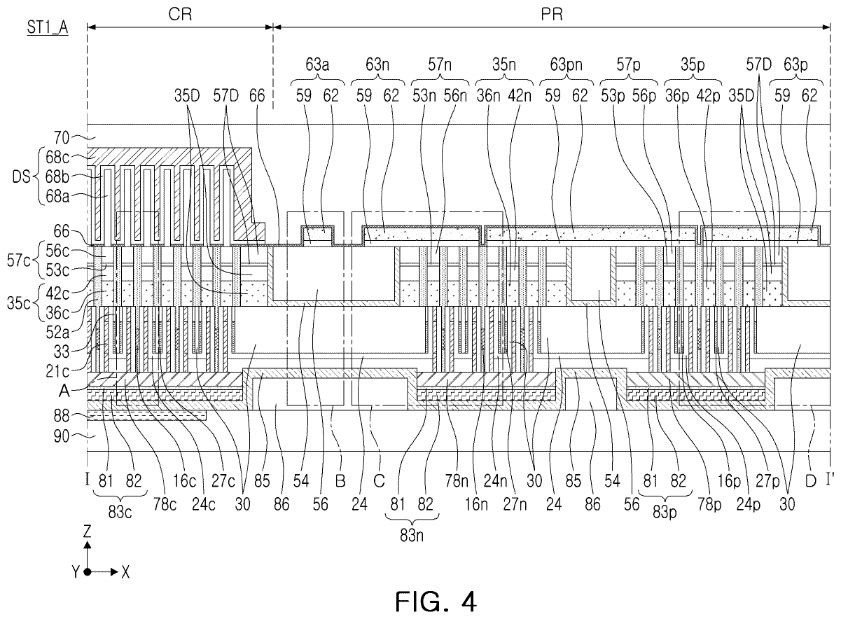

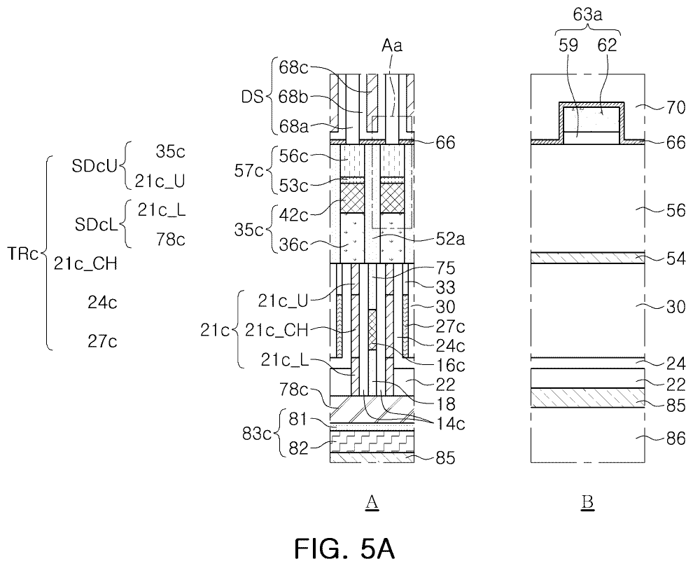

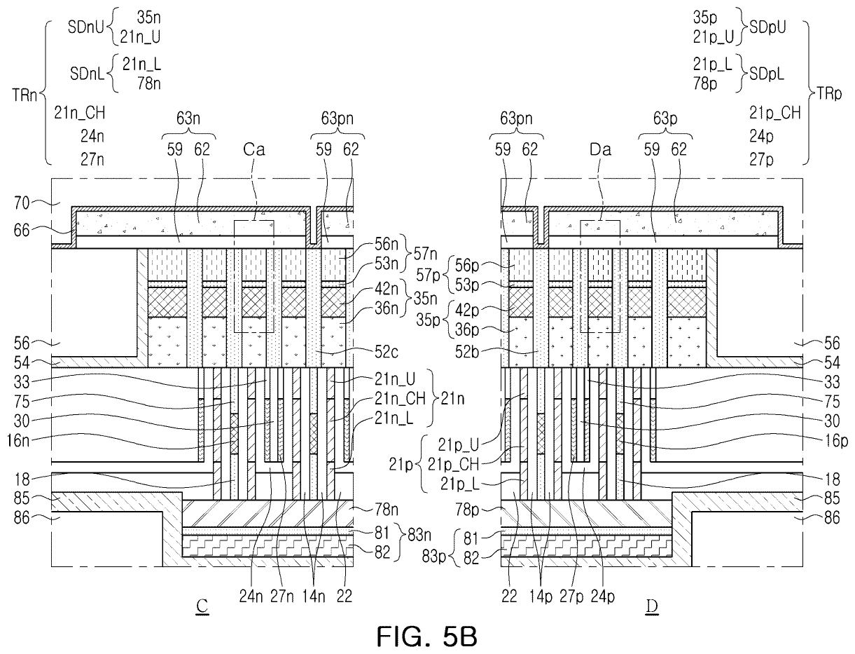

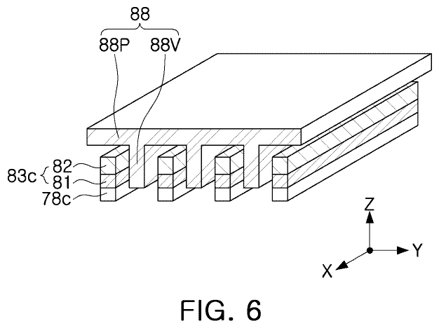

An example of a first portion ST1_A of a first structure ST1 of a semiconductor device according to some example embodiments will be described with reference to FIGS. 3, 4, 5A, 5B and 6, along with FIGS. 1 and 2. FIG. 3 is a plan diagram illustrating a semiconductor device according to some example embodiments, FIG. 4 is a cross-sectional diagram illustrating a region taken along line I-I′ in FIG. 3, FIG. 5A is an enlarged diagram illustrating regions “A” and “B” in FIG. 4, FIG. 5B is an enlarged diagram illustrating regions “C” and “D” in FIG. 4, and FIG. 6 is a perspective diagram illustrating an example of a bit line shield structure 88.

Referring to FIGS. 1, 2, 3, 4, 5A, 5B and 6, the first structure ST1 of the semiconductor device 1 may include a memory region CR and a peripheral region PR. In the description below, the memory region CR and the peripheral region PR in the first portion ST1_A of the first structure ST1 of the semiconductor device 1 will be mainly described.

The memory region CR may include cell vertical active patterns 21c, cell gate electrodes 27c, cell upper source/drain patterns 35c, cell contact plugs 57c, and a cell isolation pattern 52a. The peripheral region PR may include first peripheral vertical active patterns 21n, first peripheral gate electrodes 27n, first peripheral upper source/drain patterns 35n, first peripheral contact plugs 57n, and a first peripheral isolation pattern 52c. The peripheral region PR may further include second peripheral vertical active patterns 21p, second peripheral gate electrodes 27p, second peripheral upper source/drain patterns 35p, second peripheral contact plugs 57p, and a second peripheral isolation pattern 52b.

Each of the cell vertical active patterns 21c may include a cell lower source/drain region 21c_L, a cell vertical channel region 21c_CH on the cell lower source/drain region 21c_L, and a cell upper source/drain region 21c_U on the cell vertical channel region 21c_CH. Each of the first peripheral vertical active patterns 21n may include a first peripheral lower source/drain region 21n_L, a first peripheral vertical channel region 21n_CH on the first peripheral lower source/drain region 21n_L, and a first peripheral upper source/drain region 21n_U on the first peripheral vertical channel region 21n_CH.

The cell gate electrodes 27c may be the wordlines WL described with reference to FIG. 2. The cell gate electrodes 27c may have side surfaces facing side surfaces of the cell vertical active patterns 21c. The first peripheral gate electrodes 27n may have side surfaces facing side surfaces of the first peripheral vertical active patterns 21n. The second peripheral gate electrodes 27p may have side surfaces facing side surfaces of the second peripheral vertical active patterns 21p.

Each of the cell upper source/drain patterns 35c may include a first cell upper source/drain pattern 36c and a second cell upper source/drain pattern 42c stacked in order. Side surfaces of the first cell upper source/drain pattern 36c and the second cell upper source/drain pattern 42c may be aligned. Each of the first peripheral upper source/drain patterns 35n may include a first-1 peripheral upper source/drain pattern 36n and a first-2 peripheral upper source/drain pattern 42n stacked in order. Side surfaces of the first-1 peripheral upper source/drain pattern 36n and the first-2 peripheral upper source/drain pattern 42n may be aligned. Each of the second peripheral upper source/drain patterns 35p may include a second-1 peripheral upper source/drain pattern 36p and a second-2 peripheral upper source/drain pattern 42p stacked in order. Side surfaces of the second-1 peripheral upper source/drain pattern 36p and the second-2 peripheral upper source/drain pattern 42p may be aligned.

The cell upper source/drain patterns 35c may have N-type conductivity. The first peripheral upper source/drain patterns 35n may have N-type conductivity. The second peripheral upper source/drain patterns 35p may have P-type conductivity.

The second cell upper source/drain pattern 42c may have a concentration of impurities higher than a concentration of impurities of the first cell upper source/drain pattern 36c. The first cell upper source/drain pattern 36c may have a concentration of impurities higher than the concentration of impurities of the first cell upper source/drain region 21c_U. The first-2 peripheral upper source/drain pattern 42n may have a concentration of impurities higher than the concentration of impurities of the first-1 peripheral upper source/drain pattern 36n. The first-1 peripheral upper source/drain pattern 36n may have a concentration of impurities higher than the concentration of impurities of the first peripheral upper source/drain region 21n_U. The second-2 peripheral upper source/drain pattern 42p may have a concentration of impurities higher than the concentration of impurities of the second-1 peripheral upper source/drain pattern 36p. The concentration of impurities of the second-1 peripheral upper source/drain pattern 36p may have a concentration of impurities higher than the concentration of impurities of the second peripheral upper source/drain region 21p_U.

The upper source/drain patterns 35c, 35n, and 35p may vertically overlap the vertical active patterns 21c, 21n, and 21p and may be in contact with the vertical active patterns 21c, 21n, and 21p. A width in the first horizontal direction of each of the upper source/drain patterns 35c, 35n, and 35p may be greater than a width in the first horizontal direction of each of the vertical active patterns 21c, 21n, and 21p. The memory region CR and the peripheral region PR may further include dummy source/drain patterns 35D disposed on the same level as the upper source/drain patterns 35c, 35n, and 35p, formed of the same material as a material of the upper source/drain patterns 35c, 35n, and 35p and having the same structure as a structure of the upper source/drain patterns 35c, 35n, and 35p. The dummy source/drain patterns 35D may be spaced apart from the vertical active patterns 21c, 21n, and 21p.

The cell contact plugs 57c may be disposed on the cell upper source/drain patterns 35c. Each of the cell contact plugs 57c may include a metal-semiconductor compound layer 53c in contact with an upper surface of the second cell upper source/drain pattern 42c and a plug pattern 56c on the metal-semiconductor compound layer 53c. The cell upper source/drain patterns 35c and the cell contact plugs 57c, which are stacked in order, may have side surfaces aligned with each other.

The first peripheral contact plugs 57n may be disposed on the first peripheral upper source/drain patterns 35n. Each of the first peripheral contact plugs 57n may include a metal-semiconductor compound layer 53n in contact with an upper surface of the first-2 peripheral upper source/drain pattern 42n and a plug pattern 56n on the metal-semiconductor compound layer 53n. The first peripheral upper source/drain patterns 35n and the first peripheral contact plugs 57n, which are stacked in order, may have side surfaces aligned with each other.

The second peripheral contact plugs 57p may be disposed on the second peripheral upper source/drain patterns 35p. Each of the second peripheral contact plugs 57p may include a metal-semiconductor compound layer 53p in contact with an upper surface of the second-2 peripheral upper source/drain pattern 42p and a plug pattern 56p on the metal-semiconductor compound layer 53p. The second peripheral upper source/drain patterns 35p and the second peripheral contact plugs 57p, which are stacked in order, may have side surfaces aligned with each other.

The contact plugs 57c, 57n, and 57p may be aligned with and in contact with the upper source/drain patterns 35c, 35n, and 35p. The memory region CR and the peripheral region PR may further include dummy contact plugs 57D aligned with and in contact with the dummy source/drain patterns 35D. The dummy contact plugs 57D may be disposed on the same level as the contact plugs 57c, 57n, and 57p, may be formed of the same material as a material of the contact plugs 57c, 57n, and 57p and may have the structure as a structure of the contact plugs 57c, 57n, and 57p.

The cell isolation pattern 52a may define side surfaces of the cell upper source/drain patterns 35c and the cell contact plugs 57c, which are stacked in order. The first peripheral isolation pattern 52c may define side surfaces of the first peripheral upper source/drain patterns 35n and the first peripheral contact plugs 57n, which are stacked in order. The second peripheral isolation pattern 52b may define side surfaces of the second peripheral upper source/drain patterns 35p and the second peripheral contact plugs 57p, which are stacked in order. The cell isolation pattern 52a may surround the side surfaces of the cell upper source/drain patterns 35c and the cell contact plugs 57c, which are stacked in order, the first peripheral isolation pattern 52c may surround the side surfaces of the first peripheral upper source/drain patterns 35n and the first peripheral contact plugs 57n, which are stacked in order, and the second peripheral isolation pattern 52b may surround the side surfaces of the second peripheral upper source/drain patterns 35p and the second peripheral contact plugs 57p, which are stacked in order. The cell isolation pattern 52a, the first peripheral isolation pattern 52c and the second peripheral isolation pattern 52b may be disposed on the same level and may include the same insulating material.

The peripheral region PR may further include conductive patterns 63a, 63n, 63pn, and 63p disposed on the same level and including the same material. The memory region CR and the peripheral region PR may further include an insulating liner 66.

The conductive patterns 63a, 63n, 63p and 63pn may include a pad pattern 63a, a first upper wiring 63n, a second upper wiring 63p, and an upper connection wiring 63pn.

The first upper wiring 63n may be connected to a portion of the first peripheral contact plugs 57n. The second upper wiring 63p may be connected to a portion of the second peripheral r contact plugs 57p. The upper connection wiring 63pn may electrically connect a portion of the first peripheral contact plugs 57n to a portion of the second peripheral contact plugs 57p. The pad pattern 63a may not vertically overlap the first and second peripheral contact plugs 57n and 57p.

The insulating liner 66 may be disposed on the cell contact plugs 57c, the cell isolation pattern 52a, and the conductive patterns 63a, 63n, 63pn, and 63p. The insulating liner 66 may cover upper surfaces of the cell contact plugs 57c and the cell isolation pattern 52a in the memory region CR, and may cover upper surfaces and side surfaces of the conductive patterns 63a, 63n, 63pn, and 63p in the peripheral region PR. The insulating liner 66 may include an insulating material such as SiN, SiBN, SiCN, or high-x dielectric.

The insulating liner 66 may include a first portion disposed on an upper surface of the cell isolation pattern 52a and a second portion disposed on upper surfaces of the first and second upper wirings 63 and 63p, and the second portion of the insulating liner 66 may be disposed on a level higher than a level of the first portion of the insulating liner 66.

The memory region CR and the peripheral region PR may further include a data storage structure DS and an insulating layer 70.

The data storage structure DS may include first electrodes 68a connected to the cell plug patterns 57c in the memory region CR, penetrating the insulating liner 66, and extending in the vertical direction Z, a second electrode 68c on a side surface and an upper surface of each of the first electrodes 68a, and a dielectric layer 68b between the first electrodes 68a and the second electrode 68c. The data storage structure DS may be configured as a cell capacitor of a memory such as a DRAM.

The insulating layer 70 may cover the data storage structure DS in the memory region CR and the insulating liner 66 in the peripheral region PR. The insulating layer 70 may include at least one of silicon oxide or low-x dielectric.

The memory region CR and the peripheral region PR may include lower source/drain patterns 78c, 78n, and 78p connected to the vertical active patterns 21c, 21n, and 21p below the vertical active patterns 21c, 21n, and 21p, and conductive patterns 83c, 83n, and 83p aligned with the lower source/drain patterns 78c, 78n, and 78p below the lower source/drain patterns 78c, 78n, and 78p.

The lower source/drain patterns 78c, 78n, and 78p may include a cell lower source/drain pattern 78c connected to the cell vertical active patterns 21c, a first peripheral lower source/drain pattern 78n connected to the first peripheral vertical active patterns 21n, and a second peripheral lower source/drain pattern 78p connected to the first peripheral vertical active patterns 21p.

The conductive patterns 83c, 83n, and 83p may include a bit line 83c in contact with and aligned with the cell lower source/drain pattern 78c, a first lower wiring 83n in contact with and aligned with the first peripheral lower source/drain pattern 78n, and a second lower wiring 83p in contact with and aligned the second peripheral lower source/drain pattern 78p. Each of the conductive patterns 83c, 83n, and 83p may include a first conductive layer 81 and a second conductive layer 82 disposed below the first conductive layer 81. The bit line 83c may be the bit line BL described with reference to FIG. 2.

The memory region CR may further include cell gate dielectric layers 24c, cell back gate electrodes 16c, cell back gate dielectric layers 14c, and insulating layers 18, 33, 30, and 75. The peripheral region PR may further include first peripheral gate dielectric layers 24n, first peripheral back gate electrodes 16n, first peripheral back gate dielectric layers 14n, second peripheral gate dielectric layers 24p, second peripheral back gate electrodes 16p, second peripheral back gate dielectric layers 14p, insulating layers 18, 33, 30, and 75, and insulating structures 54 and 56.

The cell back gate electrodes 16c may be the back gate lines BG described with reference to FIG. 2. Each of the cell gate electrodes 27c may extend in the second horizontal direction Y. The cell gate electrodes 27c may be spaced apart from each other in the first horizontal direction X, perpendicular to the second horizontal direction Y. Each of the cell back gate electrodes 16c may be configured as a line shape extending in the second horizontal direction Y.

A pair of cell gate electrodes 27c adjacent to each other in the first horizontal direction X among the cell gate electrodes 27c may be disposed between a pair of the cell back gate electrodes 16c adjacent to each other in the first horizontal direction X among the cell back gate electrodes 16c. On the plane, each of the cell vertical active patterns 21c may be configured as a bar shape extending in the second horizontal direction Y. Each of the cell vertical active patterns 21c may be disposed between the cell back gate electrode 16c and the cell gate electrode 27c adjacent to each other among the cell back gate electrodes 16c and the cell gate electrodes 27c.

Each of the first peripheral gate electrodes 27n may extend in the second horizontal direction Y. Each of the first peripheral back gate electrodes 16n may be configured as a line shape extending in the second horizontal direction Y. A pair of first peripheral gate electrodes 27n adjacent to each other in the first horizontal direction among the first peripheral gate electrodes 27n may be disposed between a pair of the first peripheral back gate electrodes 16n adjacent to each other in the first horizontal direction X. On the plane, each of the first peripheral vertical active patterns 21n may be configured as a bar shape extending in the second horizontal direction Y. Each of the first peripheral vertical active patterns 21n may be disposed between the first peripheral back gate electrode 16n and the first peripheral gate electrode 27n adjacent to each other among the first peripheral back gate electrodes 16n and the first peripheral gate electrodes 27n.

Each of the second peripheral gate electrodes 27p may extend in the second horizontal direction Y. Each of the second peripheral back gate electrodes 16p may be configured as a line shape extending in the second horizontal direction Y. A pair of second peripheral gate electrodes 27p adjacent to each other in the first horizontal direction X among the second peripheral gate electrodes 27p may be disposed between a pair of the second peripheral back gate electrodes 16p adjacent to each other in the first horizontal direction X. On a plane, each of the second peripheral vertical active patterns 21p may be configured as a bar shape extending in the second horizontal direction Y. Each of the second peripheral vertical active patterns 21p may be disposed between the second peripheral back gate electrode 16p and the second peripheral gate electrode 27p adjacent to each other among the second peripheral back gate electrodes 16p and the second peripheral gate electrodes 27p.

The cell gate dielectric layers 24c may be disposed between side surfaces of the cell vertical active patterns 21c and the cell gate electrodes 27c. The cell gate dielectric layers 24c may extend to cover lower surfaces of the cell gate electrodes 27c. The first peripheral gate dielectric layers 24n may be disposed between side surfaces of the first peripheral vertical active patterns 21n and the first peripheral gate electrodes 27n. The first peripheral gate dielectric layers 24n may extend to cover lower surfaces of the first peripheral gate electrodes 27n. The second peripheral gate dielectric layers 24p may be disposed between side surfaces of the second peripheral vertical active patterns 21p and the second peripheral gate electrodes 27p. The second peripheral gate dielectric layers 24p may extend to cover lower surfaces of the second peripheral gate electrodes 27p.

The cell back gate dielectric layers 14c may be disposed between the cell vertical active patterns 21c and the cell back gate electrodes 16c. The first peripheral back gate dielectric layers 14n may be disposed between the first peripheral vertical active patterns 21n and the first peripheral back gate electrodes 16n. The second peripheral back gate dielectric layers 14p may be disposed between the second peripheral vertical active patterns 21p and the second peripheral back gate electrodes 16p.

The insulating layers 18 may be disposed below lower surfaces of the back gate electrodes 16c, 16n, and 16p. The insulating layers 75 may be disposed on upper surfaces of the back gate electrodes 16c, 16n, and 16p. The insulating layers 33 may be disposed on upper surfaces of the gate electrodes 27c, 27n, and 27p. Each of the insulating layers 30 may be disposed between the gate electrodes adjacent to each other among the gate electrodes 27c, 27n, and 27p, and between the insulating layers adjacent to each other among the insulating layers 33. The insulating layers 22 may be disposed between lower surfaces of the gate dielectric layers 24c, 24n, and 24p and the lower source/drain patterns 78c, 78n, and 78p.

Each of the insulating structures 54 and 56 may be disposed between groups adjacent to each other among a group of the cell isolation patterns 52a, a group of the first peripheral isolation patterns 52c, and a group of the second peripheral isolation patterns 52b. Each of the insulating structures 54 and 56 may include an insulating pattern 56 and an insulating liner 54 covering a side surface and a lower surface of the insulating pattern 56. The insulating pattern 56 may include an oxide, and the insulating liner 54 may include a nitride. The pad pattern 63a may be disposed on upper surfaces of the insulating structures 54 and 56.

The memory region CR may further include a bit line shield structure 88, and the memory region CR and the peripheral region PR may further include insulating structures 85 and 86 and an insulating layer 90.

The insulating structures 85 and 86 may include an insulating pattern 86 and an insulating liner 85. The insulating liner 85 may cover an upper surface of the insulating pattern 86, side surfaces of the lower source/drain patterns 78c, 78n, and 78p, and side surfaces and lower surfaces of the conductive patterns 83c, 83n, and 83p.

The bit line shield structure 88 may include vertical portions disposed between the bit lines 83c (88V in FIG. 6) and a plate portion (88P in FIG. 6) extending from the vertical portions 88V and vertically overlapping the bit lines 83c. The bit line shield structure 88 may be spaced apart from the bit lines 83c by the insulating liner 85. The insulating layer 90 may be disposed below the insulating structure 85 and 86 and the bit line shield structure 88.

The vertical active patterns 21c, 21n, and 21p may include single crystal silicon.

The cell upper source/drain patterns 35c and the first peripheral upper source/drain patterns 35n may include first polysilicon, for example, polysilicon having N-type conductivity. The second peripheral upper source/drain patterns 35p may include second polysilicon, for example, polysilicon having P-type conductivity.

The cell lower source/drain pattern 78c and the first peripheral lower source/drain pattern 78n may include a third polysilicon, for example, N-type polysilicon. The second peripheral lower source/drain pattern 78p may include fourth polysilicon, for example, P-type polysilicon.

A width in the first horizontal direction X of each of the upper source/drain patterns 35c, 35n, and 35p may be greater than a width in the first horizontal direction X of each of the vertical active patterns 21c, 21n, and 21p.

The cell upper source/drain SDcU may include the cell upper source/drain pattern 35c and the cell upper source/drain region 21c_U. The cell lower source/drain SDcL may include the cell lower source/drain pattern 78c and the cell lower source/drain region 21c_L. The cell upper source/drain SDcU and the cell lower source/drain SDcL may have N-type conductivity. The cell transistor TRc may include the cell upper source/drain SDcU, the cell lower source/drain SDcL, the cell vertical channel region 21c_CH, the cell gate dielectric layer 24c and the cell gate electrode 27c.

The first peripheral upper source/drain SDnU may include the first peripheral upper source/drain pattern 35n and the first peripheral upper source/drain region 21n_U. The first peripheral lower source/drain SDnL may include the first peripheral lower source/drain pattern 78n and the first peripheral lower source/drain region 21n_L. The first peripheral upper source/drain SDnU and the first peripheral lower source/drain SDnL may have N-type conductivity. The first peripheral transistor TRn may include the first peripheral upper source/drain SDnU, the first peripheral lower source/drain SDnL, the first peripheral vertical channel region 21n_CH, the first peripheral gate dielectric layer 24n and the first peripheral gate electrode 27n. The first peripheral transistor TRn may be configured as an NMOS transistor. A plurality of the first peripheral transistor TRn may be disposed, and may be disposed in NMOS transistor regions NMOS1 and NMOS2 illustrated in FIG. 3.

The second peripheral upper source/drain SDpU may include the second peripheral upper source/drain pattern 35p and the second peripheral upper source/drain region 21p_U. The second peripheral lower source/drain SDpL may include the second peripheral lower source/drain pattern 78p and the second peripheral lower source/drain region 21p_L. The second peripheral upper source/drain SDpU and the second peripheral lower source/drain SDpL may have P-type conductivity. The second peripheral transistor TRp may include the second peripheral upper source/drain SDpU, the second peripheral lower source/drain SDpL, the second peripheral vertical channel region 21p_CH, the second peripheral gate dielectric layer 24p and the second peripheral gate electrode 27p. The second peripheral transistor TRp may be configured as a PMOS transistor. A plurality of the second peripheral transistor TRp may be disposed, and may be disposed in PMOS transistor regions PMOS1 and PMOS2 illustrated in FIG. 3.

In the description below, various modified examples of elements of some example embodiments described above will be described. Various modified examples of the elements of the above-described example embodiments described below will be described with respect to modified or replaced elements. Here, the elements described above may be referred to directly without detailed description, or the description may not be provided. Also, the elements which may be modified or replaced will be described with reference to the drawings, but the elements which may be modified or replaced may be combined with each other or with the elements described above and may be included in the semiconductor device according to some example embodiments.

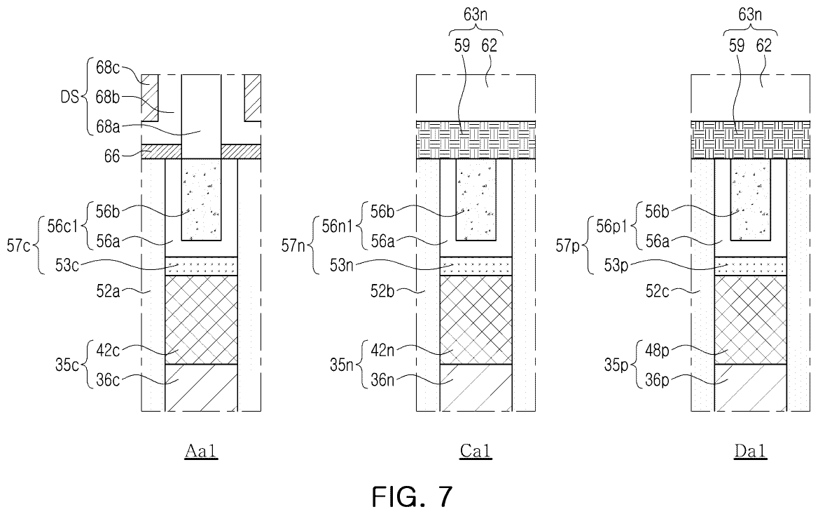

An example of a semiconductor device according to some example embodiments will be described with reference to FIG. 7. FIG. 7 is an enlarged diagram illustrating region “Aa1” corresponding to region “Aa” in FIG. 5A, region “Cal” corresponding to region “Ca” in FIG. 5B, and region “Dal” corresponding to region “Da” in FIG. 5B, illustrating an example of a semiconductor device according to some example embodiments.

Referring to FIG. 7, the plug patterns (56c in FIG. 5A) in FIGS. 5A and 5B, and 56n and 56p in FIG. 5B may be formed of a single conductive material. The plug patterns (56c in FIG. 5A, 56n and 56p in FIG. 5B) may be replaced with plug patterns 56c1, 56n1, and 56p1 including at least two conductive material layers. For example, each of the plug patterns 56c1, 56n1, and 56p1 may include a conductive material pattern 56b and a conductive liner 56a covering a side surface and a lower surface of the conductive material pattern 56b. For example the conductive liner 56a may be considered a barrier layer. However, the example embodiments are not so limited thereto.

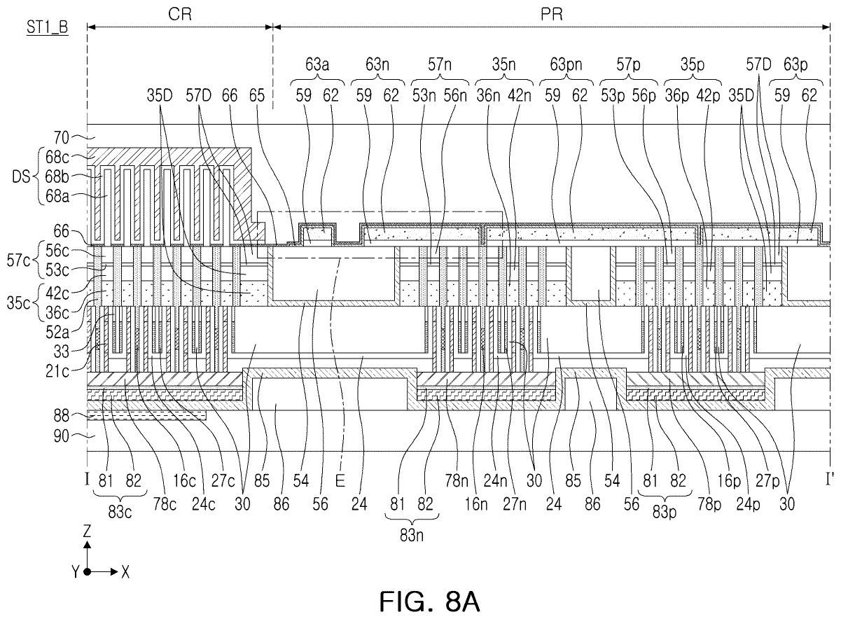

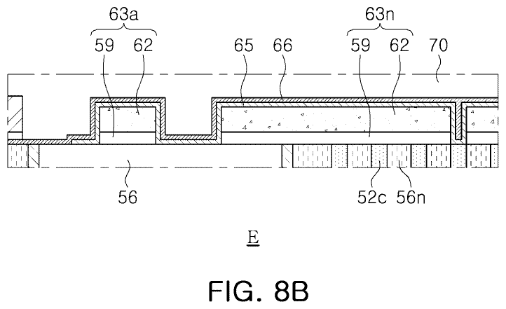

An example of a semiconductor device according to some example embodiments will be described with reference to FIGS. 8A and 8B. FIG. 8A may be a cross-sectional diagram corresponding to FIG. 4, illustrating an example of a semiconductor device according to some example embodiments, and FIG. 8B is an enlarged diagram illustrating region “E” in FIG. 8A.

Referring to FIGS. 8A and 8B, the first portion ST1_A of the first structure ST1 in FIG. 4 may be replaced with a first portion ST1_B of the first structure ST1 in FIG. 8A. The peripheral region PR may further include a buffer insulating layer 65 between the insulating liner 66 and the conductive patterns 63a, 63n, 63pn, and 63p described with reference to FIGS. 4, 5A and 5B. However, the example embodiments are not so limited thereto.

The buffer insulating layer 65 may include a material different from a material of the insulating liner 66. For example, the insulating liner 66 may include a first insulating material including at least one of SiN, SiBN, SiCN, and/or high-x dielectric, and the buffer insulating layer 65 may include a second insulating material including at least one of silicon oxide and/or low-x dielectric. The buffer insulating layer 65 may reduce parasitic capacitance between conductive patterns adjacent to each other among the conductive patterns 63a, 63n, 63pn, and 63p. Accordingly, the buffer insulating layer 65 may prevent or reduce in likelihood a signal transmission speed from being lowered due to RC delay of the conductive patterns 63a, 63n, 63pn, and 63p.

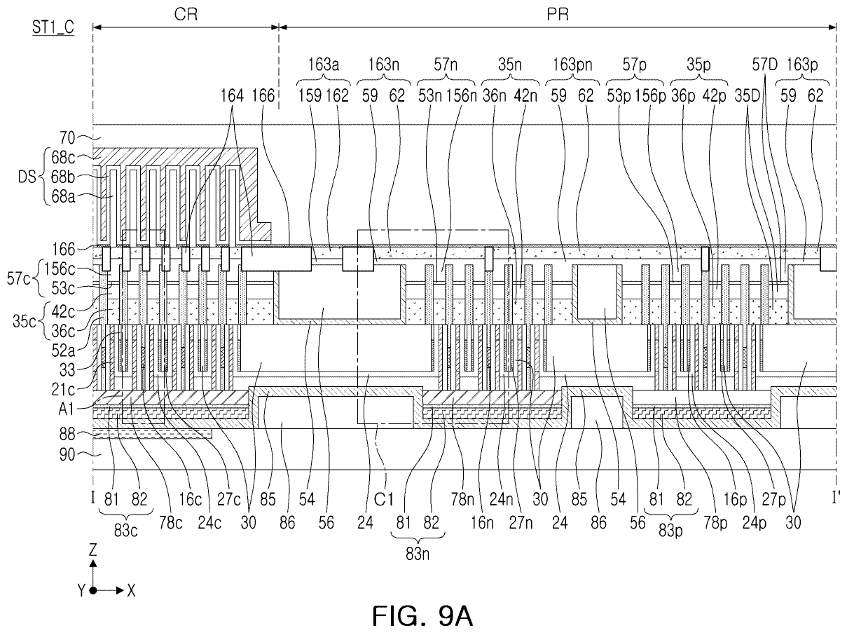

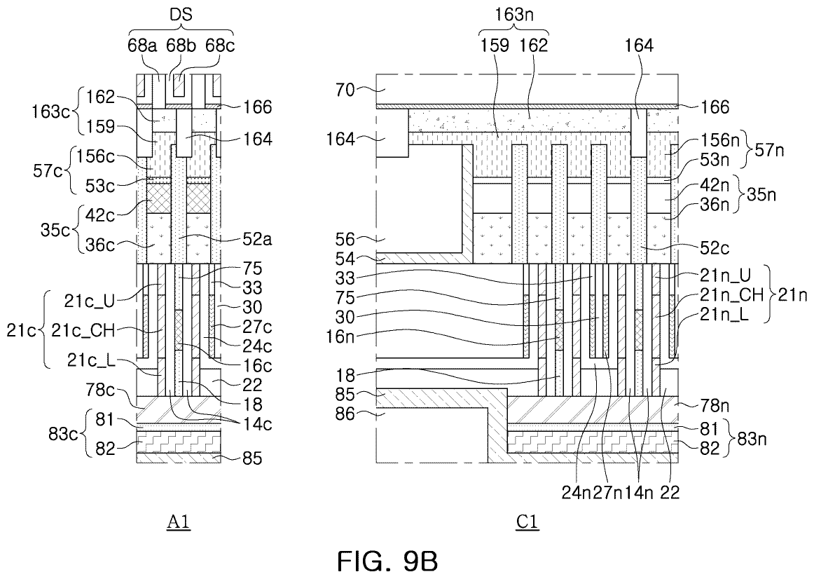

An example of a semiconductor device according to some example embodiments will be described with reference to FIGS. 9A and 9B. FIG. 9A may be a cross-sectional diagram corresponding to FIG. 4, illustrating an example of a semiconductor device according to some example embodiments, and FIG. 9B may be an enlarged diagram illustrating region “A1” and region “C1” in FIG. 9A.

Referring to FIGS. 9A and 9B, the first portion ST1_A of the first structure ST1 in FIG. 4 may be replaced with the first portion ST1_C of the first structure ST1 in FIG. 9A. The memory region CR may further include cell pad patterns 163c. The conductive patterns (63a, 63n, 63pn, and 63p in FIGS. 4, 5A and 5B) described with reference to FIGS. 4, 5A and 5B may be replaced with conductive patterns 163a, 163n, 163pn, and 163p as in FIGS. 9A and 9B. Each of the conductive patterns 163a, 163p, 163pn, and 163p and the cell pad patterns 163c may include a first conductive layer 159 and a second conductive layer 162 stacked in order. The plug patterns 56c, 56n, and 56p described with reference to FIGS. 4, 5A, and 5B may be replaced with the plug patterns 156c, 156n, and 156p as in FIGS. 9A and 9B. The first conductive layers 159 may extend from the plug patterns 156c, 156n, and 156p. The first conductive layers 159 and the plug patterns 156c, 156n, and 156p may be integrated with each other. The conductive patterns 163a, 163n, 163pn, and 163p and the cell pad patterns 163c may have upper surfaces coplanar with each other. However, the example embodiments are not so limited thereto.

The conductive patterns 163a, 163n, 163pn, and 163p may include a pad pattern 163a, a first upper wiring 163n, a second upper wiring 163p, and an upper connection wiring 163pn corresponding to the pad pattern 63a, the first upper wiring 63n, the second upper wiring 63p, and the upper connection wiring 63pn described with reference to FIGS. 4, 5A, and 5B, respectively.

The memory region CR and the peripheral region PR may further include upper isolation patterns 164. The upper isolation patterns 164 may be disposed between the conductive patterns 163a, 163n, 163pn, and 163p and the cell pad patterns 163c. The upper isolation patterns 164 may include an insulating material.

The insulating liner 66 described with reference to FIGS. 4, 5A and 5B may be replaced with an insulating liner 166 disposed on the conductive patterns 163a, 163n, 163pn, and 163p, the cell pad patterns 163c, and upper isolation patterns 164. The first electrodes 68a of the data storage structure DS may penetrate the insulating liner 166 and may be connected to the cell pad patterns 163c.

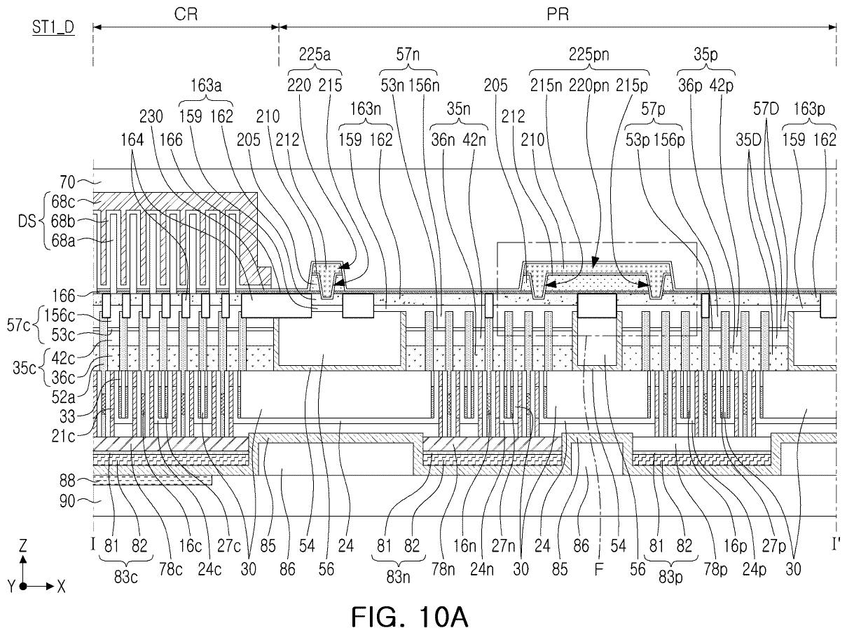

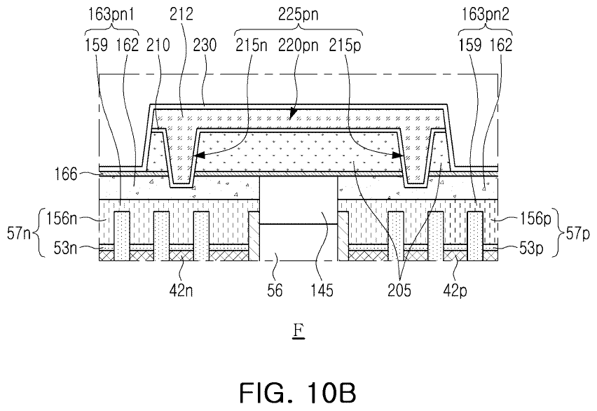

An example of a semiconductor device according to some example embodiments will be described with reference to FIGS. 10A and 10B. FIG. 10A may be a cross-sectional diagram corresponding to FIG. 9A, illustrating an example of a semiconductor device according to some example embodiments, and FIG. 10B is an enlarged diagram illustrating region “F” in FIG. 10A.

Referring to FIGS. 10A and 10B, the first portion ST1_C of the first structure ST1 in FIG. 9A may be replaced with the first portion ST1_D of the first structure ST1 in FIG. 10A. The upper connection wiring 163pn described with reference to FIGS. 9A and 9B may be divided into a first upper wiring 163n and a second upper wiring 163p. The peripheral region PR may further include upper wiring structures 205, 225a, and 225pn on the conductive patterns 163a, 163n, and 163p and the insulating liner 166. Each of the upper wiring structures 205, 225a, and 225pn may include an interlayer insulating layer 205 and conductive patterns 225a and 225pn. The interlayer insulating layer 205 may be disposed on the insulating liner 166.

The conductive patterns 225a and 225pn may include a pad structure 225a and an upper connection wiring structure 225pn.

The pad structure 225a may include a via 215 penetrating the interlayer insulating layer 205 and the insulating liner 166 and connected to the pad pattern 163a, and a pad portion 220 disposed on the via 215 and the interlayer insulating layer 205. The via 215 may extend from the pad portion 220.

The upper connection wiring structure 225pn may include a first via 215n penetrating the interlayer insulating layer 205 and the insulating liner 166 and connected to the first upper wiring 163n, a second via 215p penetrating the interlayer insulating layer 205 and the insulating liner 166 and connected to the second upper wiring 163p, and a wiring portion 220pn connected to the first and second vias 215n and 215p and disposed on the interlayer insulating layer 205.

The wiring portion 220pn may vertically overlap the first and second upper wirings 163n and 163p. The first and second vias 215n and 215p may extend from the wiring portion 220pn. The first and second vias 215n and 215p may be disposed between the wiring portion 220pn and the first and second upper wirings 163n and 163p, and may electrically connect the wiring portion 220pn to the first and second upper wirings 163n and 163p.

Each of the conductive patterns 225a and 225pn may include a first conductive material layer 210 and a second conductive material layer 212 on the first conductive material layer 210.

The memory region CR and the peripheral region PR may further include the insulating liner 166 and the upper insulating liner 230 disposed on the upper wiring structures 205, 225a, and 225pn. The upper insulating liner 230 may be disposed on the insulating liner 166 and may cover side surfaces and upper surfaces of the upper wiring structures 205, 225a, and 225pn.

The first electrodes 68a of the data storage structure DS may penetrate the insulating liner 166 and the upper insulating liner 230 and may be connected to the cell pad patterns 163c.

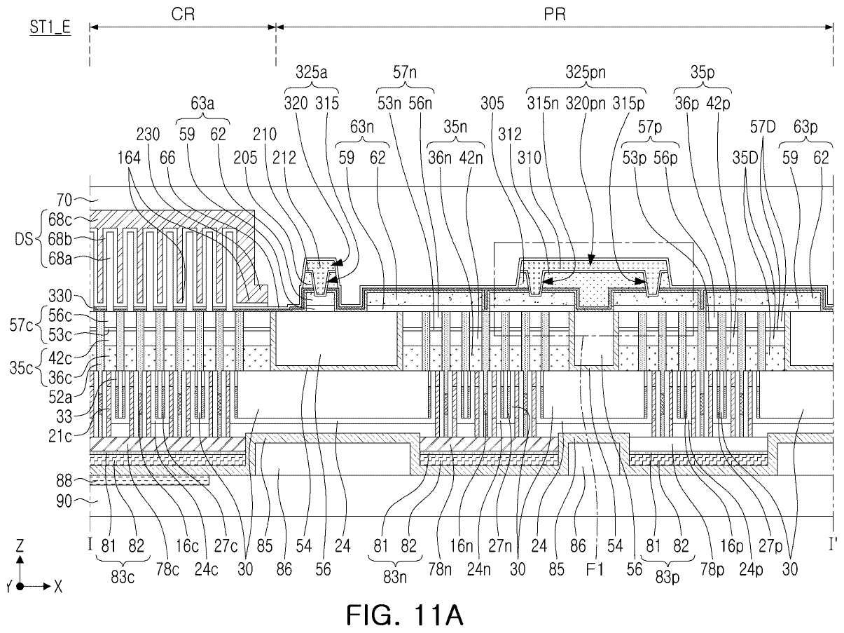

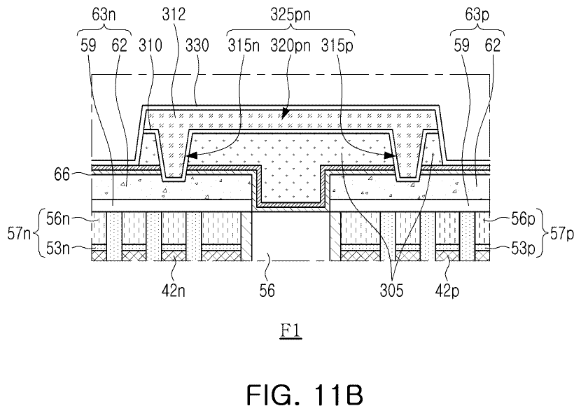

An example of a semiconductor device according to some example embodiments will be described with reference to FIGS. 11A and 11B. FIG. 11A may be a cross-sectional diagram corresponding to FIG. 8A, illustrating an example of a semiconductor device according to some example embodiments, and FIG. 11B is an enlarged diagram illustrating region “F1” in FIG. 11A.

Referring to FIGS. 11A and 11B, the first portion ST1_A of the first structure ST1 in FIG. 4 may be replaced with the first portion ST1_E of the first structure ST1 in FIG. 11A. The upper connection wiring 63pn described with reference to FIG. 8A may be divided into a first upper wiring 63n and a second upper wiring 63p. The peripheral region PR may further include upper wiring structures 305, 325a, and 325pn corresponding to the upper wiring structures 205, 225a, and 225pn described with reference to FIGS. 10A and 10B. The upper wiring structures 305, 325a, 325pn may be disposed on the conductive patterns 63a, 63n, and 63p and the insulating liner 66.

Each of the upper wiring structures 305, 325a, and 325pn may include an interlayer insulating layer 305 and conductive patterns 325a and 325pn.

The interlayer insulating layer 305 may be disposed on the insulating liner 66.

The conductive patterns 325a and 325pn may include a pad structure 325a and an upper connection wiring structure 325pn.

The pad structure 325a may include a via 315 penetrating the interlayer insulating layer 305 and the insulating liner 66 and connected to the pad pattern 63a, and a pad portion 320 disposed on the via 315 and the interlayer insulating layer 305. The via 315 may extend from the pad portion 320.

The upper connection wiring structure 325pn may include a first via 315n penetrating the interlayer insulating layer 305 and the insulating liner 66 and connected to the first upper wiring 63n, a second via 315p penetrating the interlayer insulating layer 305 and the insulating liner 66 and connected to the second upper wiring 63p, and a wiring portion 320pn connected to the first and second vias 315n and 315p and disposed on the interlayer insulating layer 305. The first and second vias 315n and 315p may extend from the wiring portion 320pn.

Each of the conductive patterns 325a and 325pn may include a first conductive material layer 310 and a second conductive material layer 312 on the first conductive material layer 310.

The memory region CR and the peripheral region PR may further include the insulating liner 66 and the upper insulating liner 330 disposed on the upper wiring structures 305, 325a, and 225pn. The upper insulating liner 330 may be disposed on the insulating liner 66 and may cover side surfaces and upper surfaces of the upper wiring structures 325a and 325pn.

The first electrodes 68a of the data storage structure DS may penetrate the insulating liner 66 and the upper insulating liner 330 and may be connected to the cell contact plugs 57c.

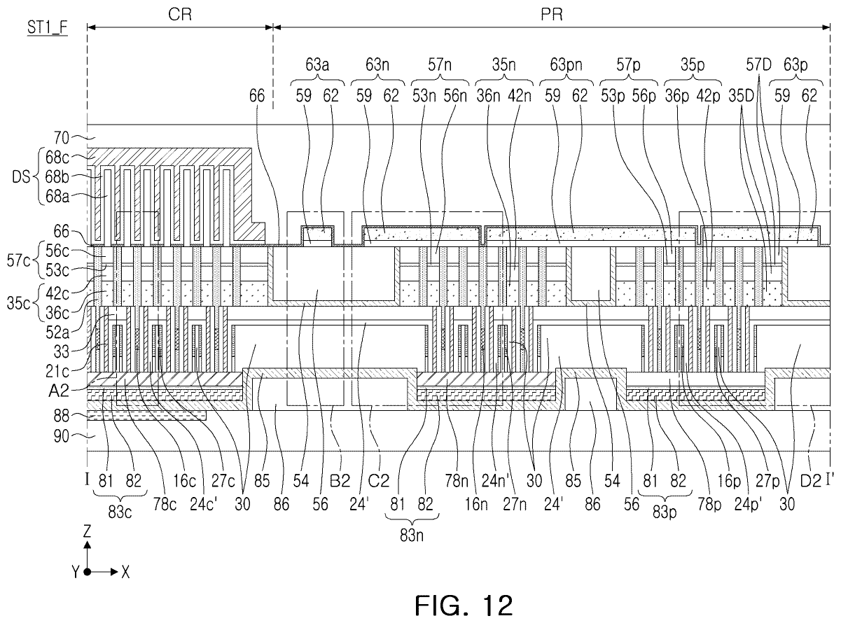

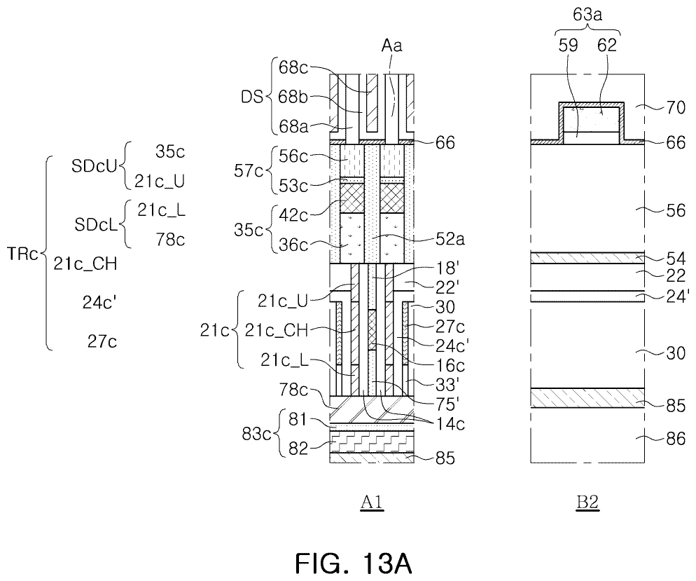

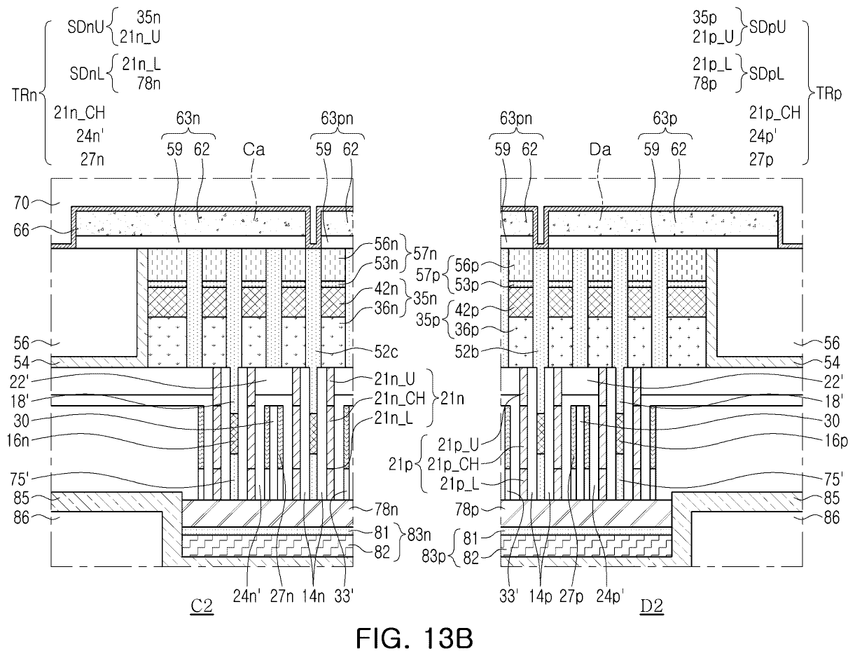

An example of a semiconductor device according to some example embodiments will be described with reference to FIGS. 12, 13A and 13B. FIG. 12 may be a cross-sectional diagram corresponding to FIG. 4, illustrating an example of a semiconductor device according to some example embodiments, FIG. 13A is an enlarged diagram illustrating regions “A2” and “B2,” and FIG. 13B is an enlarged diagram illustrating regions “C2” and “D2.”

Referring to FIGS. 12, 13A and 13B, the first portion ST1_A of the first structure ST1 in FIG. 4 may be replaced with the first portion ST1_F of the first structure ST1 in FIG. 12. The cell gate dielectric layers 24c, the first peripheral gate dielectric layers 24n, the second peripheral gate dielectric layers 24p, and the insulating layers 18, 33, and 75 described with reference to FIGS. 4, 5A and 5B may be replaced with cell gate dielectric layers 24c′, first peripheral gate dielectric layers 24n′, second peripheral gate dielectric layers 24p′, and insulating layers 18′, 33′, 75′ as in FIGS. 12, 13A and 13B.

The cell gate dielectric layers 24c′ may be disposed between side surfaces of the cell vertical active patterns 21c and the cell gate electrodes 27c, and may extend to cover upper surfaces of the cell gate electrodes 27c. The first peripheral gate dielectric layers 24n′ may be disposed between the side surfaces of the first peripheral vertical active patterns 21n and the first peripheral gate electrodes 27n, and may extend to cover upper surfaces of the first peripheral gate electrodes 27n. The second peripheral gate dielectric layers 24p′ may be disposed between side surfaces of the second peripheral vertical active patterns 21p and the second peripheral gate electrodes 27p, and may extend to cover upper surfaces of the second peripheral gate electrodes 27p.

The insulating layers 18′ may be disposed on upper surfaces of the back gate electrodes 16c, 16n, and 16p. The insulating layers 75′ may be disposed below lower surfaces of the back gate electrodes 16c, 16n, and 16p. The insulating layers 33′ may be disposed below lower surfaces of the gate electrodes 27c, 27n, and 27p. The insulating layers 22′ may be disposed on upper surfaces of the gate dielectric layers 24c′, 24n′, and 24p′.

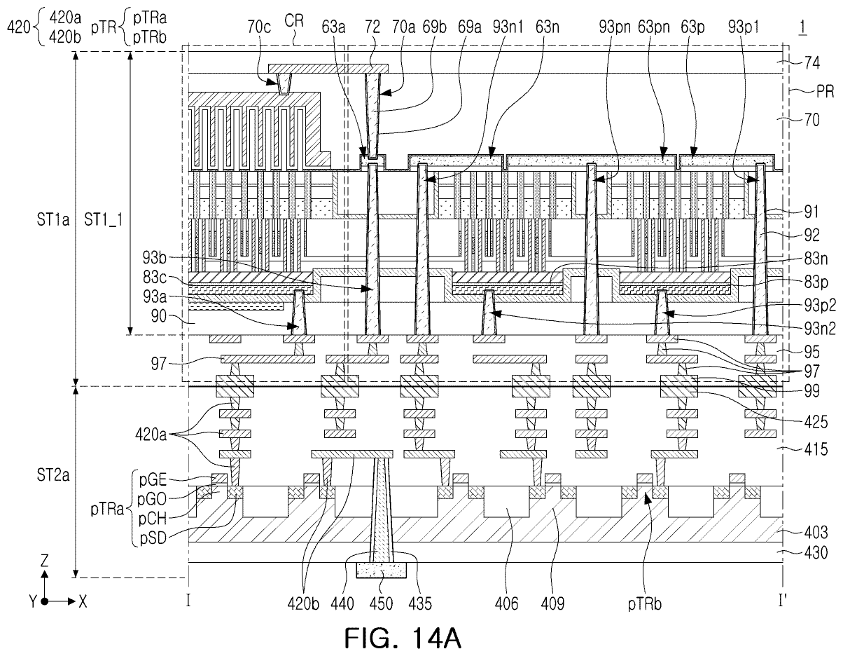

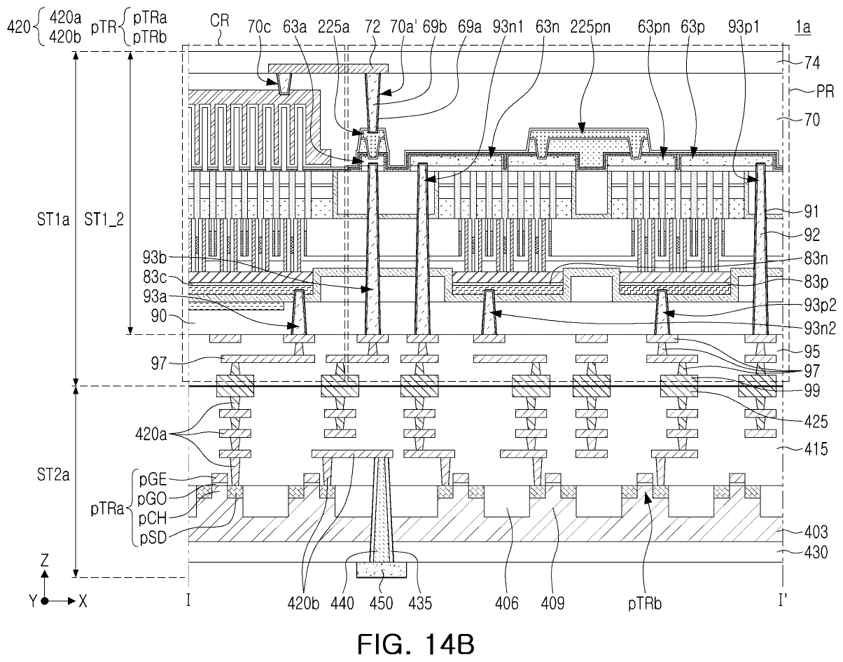

In the description below, various examples of the semiconductor device 1 described with reference to FIG. 1 will be described with reference to FIGS. 14A, 14B, 15A, 15B, 16 and 17. FIGS. 14A, 14B, 15A, 15B, 16 and 17 are diagrams illustrating various examples of the semiconductor device 1 described with reference to FIG. 1.

Referring to FIGS. 1 and 14A, the semiconductor device 1 may include a first structure ST1a corresponding to the first structure ST1 in FIG. 1 and a second structure ST2a corresponding to the second structure ST2 in FIG. 1. The second structure ST2a may be disposed below the first structure ST1a and may be in contact with and bonded to the first structure ST1a.

The first structure ST1a may include the first portion ST1_1, which is the same as one of the first portions ST1_A, ST1_B, ST1_C, ST1_D, ST1_E, and ST1_F described with reference to FIGS. 4 to 13B. For example, the first portion ST1_1 may be the same as the first portion ST1_A in FIG. 4.

The first structure ST1a may further include an insulating layer 74 on the first portion ST1_1, and an insulating layer 95 below the first portion ST1_1.

The first structure ST1a may further include upper contact plugs 70a and 70c and an upper wiring 72. Each of the contact plugs 70a may include a conductive plug pattern 69b and a conductive liner 69a covering a side surface and a lower surface of the conductive plug pattern 69b.

The upper contact plugs 70a and 70c may include a cell contact plug 70c penetrating the insulating layer 70 and connected to the second electrode 68c, and a connection contact plug 70a penetrating the insulating layer 70 and the insulating liner 66 and connected to the pad pattern 63a.

The upper wiring 72 may be connected to the contact plugs 70a and 70c on the contact plugs 70a and 70c and the insulating layer 70. The insulating layer 74 may be disposed on the insulating layer 70 and the upper wiring 72.

The first structure ST1a may further include upper contact plugs 70a and 70c and an upper wiring 72. Each of the contact plugs 70a may include a conductive plug pattern 69b and a conductive liner 69a covering a side surface and a lower surface of the conductive plug pattern 69b.

The first structure ST1a may further include lower contact plugs 93b, 93a, 93n1, 93n2, 93pn, 93p2, and 93p1 penetrating the insulating layer 90 and extending upwardly.

Each of the lower contact plugs 93b, 93a, 93n1, 93n2, 93pn, 93p2, and 93p1 may include a conductive plug pattern 92 and a conductive liner 91 covering a lower surface and a side surface of the conductive plug pattern 92.

The lower contact plugs 93b, 93a, 93n1, 93n2, 93pn, 93p2, and 93p1 may include a contact plug 93a connected to and in contact with the bit line 83c, a contact plug 93b connected to and in contact with the pad pattern 63a, a contact plug 93n1 connected to and in contact with the first upper wiring 63n, a contact plug 93n2 connected to and in contact with the first lower wiring 83n, a contact plug 93pn connected to and in contact with the upper connection wiring 63pn, a contact plug 93p2 connected to and in contact with the second lower wiring 83p, and a contact plug 93p1 connected to and in contact with the second upper wiring 63p.

The first structure ST1a may form an insulating layer 95 disposed below the first portion ST1_1, a routing wiring structure disposed in the insulating layer 95 and electrically connected to the lower contact plugs 93b, 93a, 93n1, 93n2, 93pn, 93p2, and 93p1, and bonding pads 99 connected to the routing wiring structure 97. A lower surface of the insulating layer 95 and lower surfaces of the bonding pads 99 may be coplanar with each other.

The second structure ST2a may include a first peripheral circuit pTRa vertically overlapping the memory region CR and a second peripheral circuit pTRb vertically overlapping the peripheral region PR.

The second structure ST2a may include a substrate 403 and a device isolation region 406 defining the active regions 409 on the substrate 403. The substrate 403 may be configured as a semiconductor substrate.

The first and second peripheral circuits pTRa and pTRb may be disposed on the substrate 403.

Each of the first and second peripheral circuits pTRa and pTRb may include peripheral gate structures pGO and pGE disposed on the active region 409, peripheral source/drain regions pSD disposed in the active region 409 disposed on both sides of the peripheral gate structures pGO and pGE, and a peripheral channel region pCH between the peripheral source/drain regions pSD. The peripheral gate structure pGO and pGE may include a peripheral gate dielectric layer pGO and a peripheral gate electrode pGE, stacked in order.

The first and second peripheral circuits pTRa and pTRb may include a first peripheral circuit transistor pTRa vertically overlapping the memory region CR and a second peripheral circuit transistor pTRb vertically overlapping the peripheral region PR.

The second structure ST2a may further include a lower routing wiring structure 420 disposed on the substrate 403 and electrically connected to the first and second peripheral circuits pTRa and pTRb, a second bonding pads 425 disposed on the lower routing wiring structure 420, and a lower insulating structure 415. The lower insulating structure 415 may be disposed on the substrate 403 and may have an upper surface coplanar with upper surfaces of the second bonding pads 425. Upper surfaces of the second bonding pads 425 may be bonded to lower surfaces of the first bonding pads 99, and upper surfaces of the lower insulating structure 415 may be bonded to lower surfaces of the insulating layer 95.

The lower routing wiring structure 420 may include a first lower routing wiring structure 420a electrically connected to the second bonding pads 425 and a second lower routing wiring structure 420b not directly connected to the second bonding pads 425.

The second structure ST2a may further include an insulating layer 430 disposed below the substrate 403, a conductive through-via 440 penetrating the insulating layer 430 and the substrate 403 and connected to the second lower routing wiring structure 420b, an insulating spacer 435 disposed on a side surface of the conductive through-via 440, and an input/output pad 450 connected to the conductive through-via 440 below the insulating layer 430.

Referring to FIGS. 1 and 14B, the first portion ST1_1 in FIG. 14A may be replaced with the first portion ST1_2, which may be the same as the first portion ST1_D in FIG. 10A. Accordingly, the connection contact plug 70a in FIG. 14A may be replaced with a connection contact plug 70a′ in contact with and connected to the pad structure 225a. Accordingly, the semiconductor device 1a including the first portion ST1_2 may be provided.

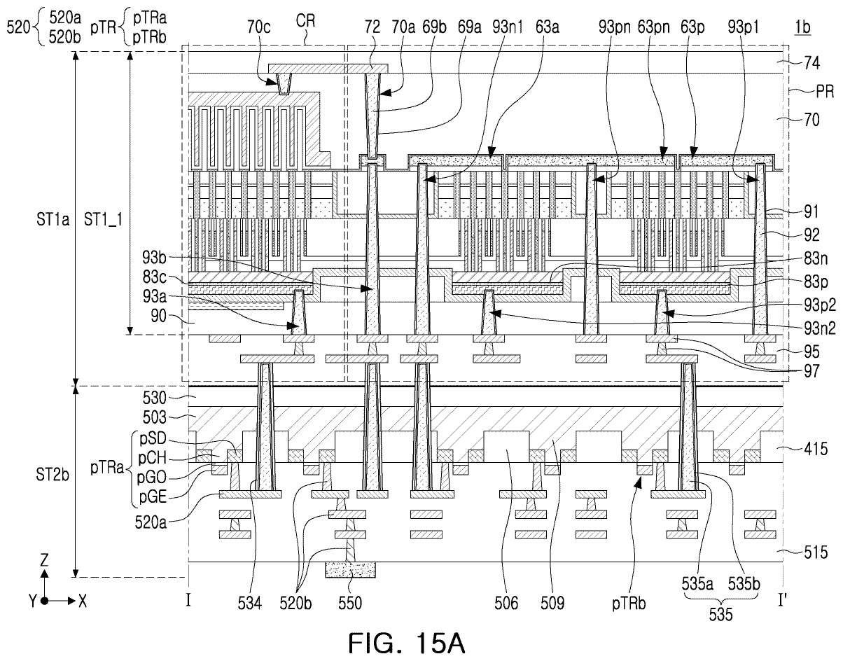

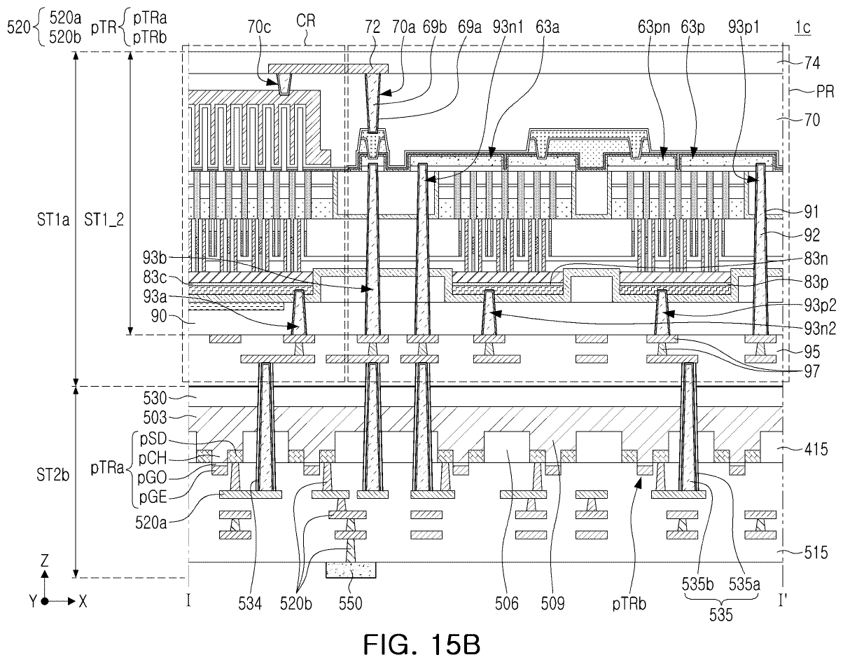

Referring to FIGS. 1 and 15A, the first bonding pads 99 in the first structure ST1a in FIG. 14A may not be provided. The second structure ST2a in FIG. 14A may be replaced with the second structure ST2b in FIG. 15A.

The second structure ST2b may include a first peripheral circuit pTRa vertically overlapping the memory region CR and a second peripheral circuit pTRb vertically overlapping the peripheral region PR.

The second structure ST2b may include a first peripheral circuit pTRa vertically overlapping the memory region CR and a second peripheral circuit pTRb vertically overlapping the peripheral region PR. The second structure ST2b may include a substrate 503 and a device isolation region 506 defining the active regions 509 below the substrate 503. The substrate 503 may be configured as a semiconductor substrate.

The first and second peripheral circuits pTRa and pTRb may be disposed below the substrate 503.

Each of the first and second peripheral circuits pTRa and pTRb may include peripheral gate structures pGO and pGE disposed below the active region 509, peripheral source/drain regions pSD disposed in the active region 509 disposed on both sides of the peripheral gate structures pGO and pGE, and a peripheral channel region pCH between the peripheral source/drain regions pSD. The peripheral gate structure pGO and pGE may include a peripheral gate dielectric layer pGO and a peripheral gate electrode pGE, stacked in order in the downward direction.

The second structure ST2b may further include a lower routing wiring structure 520 disposed below the substrate 503 and electrically connected to the first and second peripheral circuits pTRa and pTRb, and a lower insulating structure 515 covering the lower routing wiring structure 520.

The lower routing wiring structure 520 may include a first lower routing wiring structure 520a and a second lower routing wiring structure 520b.

The second structure ST2b may further include an input/output pad 550 disposed below the lower insulating structure 515 and electrically connected to the second lower routing wiring structure 520b, and an insulating layer 530 disposed between the substrate 503 and the first structure ST1a. The insulating layer 530 and the insulating layer 95 may be bonded to each other.

The first and second structures ST1a and ST2b may be electrically connected to the first lower routing wiring structure 520a and extending in the vertical direction Z, and may further include conductive through-vias 535 penetrating the substrate 503 and the insulating layer 530, and in contact with and connected to the routing wiring structure 97, and insulating spacers 534 on side surfaces of the conductive through-vias 535. The conductive through-vias 535 may include a conductive pillar 535a and a conductive liner layer 535b covering a side surface and an upper surface of the conductive pillar 535a.

Accordingly, a semiconductor device 1b including the first structure ST1a and the second structure ST2b may be provided.

Referring to FIGS. 1 and 15B, the first bonding pads 99 in the first structure ST1a in FIG. 14B may not be provided. The second structure ST2a in FIG. 14B disposed below the first structure ST1a may be replaced with the second structure ST2b described with reference to FIG. 15A. The first and second structures ST1a and ST2b may include the conductive through-vias 535 and the insulating spacers 534 the same as the examples described with reference to FIG. 15A. Accordingly, a semiconductor device 1c including the first structure ST1a and the second structure ST2b may be provided.

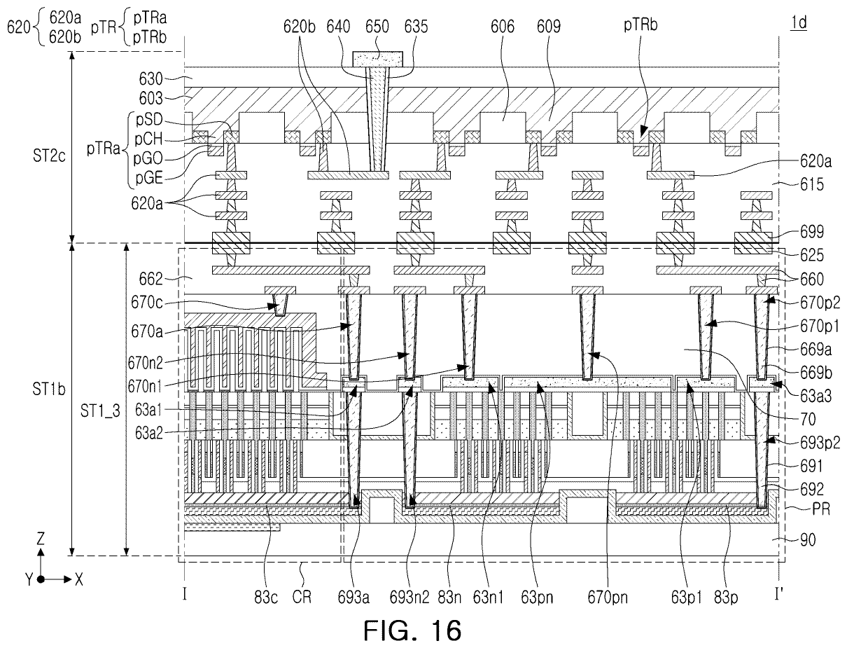

Referring to FIGS. 1 and 16, a semiconductor device id according to some example embodiments may include a first structure ST1b corresponding to the first structure ST1 in FIG. 1 and a second structure ST2c corresponding to the second structure ST2 in FIG. 1. The second structure ST2c may be disposed on the first structure ST1b and may be in contact with and bonded to the first structure ST1b.

The first structure ST1b may include the first portion ST1_3, the same as one of the first portions ST1_A, ST1_B, ST1_C, ST1_D, ST1_E, and ST1_F described with reference to FIGS. 4 to 13B. For example, the first portion ST1_3 may be the same as the first portion ST1_A in FIG. 4.

The first structure ST1b may further include first bonding pads 625 disposed in the insulating layer 662 on the first portion ST1_3, and the first bonding pads 625 are electrically connected to the routing wiring structure 660. Upper surfaces of the first bonding pads 625 may be coplanar with upper surfaces of the insulating layer 662.

The pad pattern 63a described above may include a first pad pattern 63al vertically overlapping the bit line 83c, a second pad pattern 63a2 vertically overlapping the first lower wiring 83n, and a third pad pattern 63a3 vertically overlapping the second lower wiring 83p.

The first structure ST1b may further include lower contact plugs 693a, 693n2, and 693p2 and upper contact plugs 670c, 670a, 670n2, 670n1, 670pn, 670p1, and 670p2.

The lower contact plugs 693a, 693n2, and 693p2 may include a contact plug 693a electrically connecting the bit line 83c to the first pad pattern 63al between the bit line 83c and the first pad pattern 63al, a contact plug 693n2 electrically connecting the first lower wiring 83n to the second pad pattern 63a2 between the first lower wiring 83n and the second pad pattern 63a2, and a contact plug 693p2 electrically connecting the second lower wiring 83p to the third pad pattern 63a3 between the second lower wiring 83p and the third pad pattern 63a3. Each of the lower contact plugs 693a, 693n2, and 693p2 may include a conductive liner 691 covering side surfaces and lower surfaces of the plug pattern 692 and the plug pattern 692.

The upper contact plugs 670c, 670a, 670n2, 670n1, 670pn, 670p1, and 670p2 may penetrate the insulating layer 70.

The upper contact plugs 670c, 670a, 670n2, 670n1, 670pn, 670p1, and 670p2 may include a contact plug 670c connected to the second electrode 68c, a contact plug 670a connected to the first pad pattern 63al, a contact plug 670n2 connected to the second pad pattern 63a2, a contact plug 670p2 connected to the third pad pattern 63a3, a contact plug 670n1 connected to the first upper wiring 63n1, a contact plug 670p1 connected to the second upper wiring 63p1, and a contact plug 670pn electrically connected to the upper connection wiring 63pn. Depending on the connection structure of a circuit, the contact plug 670pn may not be provided.

The upper contact plugs 670a, 670n2, 670n1, 670pn, 670p1, and 670p2 may penetrate the insulating layer 70 and the insulating liner 66. The upper contact plug 670c may penetrate the insulating layer 70. The upper contact plugs 670c, 670a, 670n2, 670n1, 670pn, 670p1, and 670p2 may be electrically connected to the routing wiring structure 660.

The second structure ST2c may include a first peripheral circuit pTRa vertically overlapping the memory region CR and a second peripheral circuit pTRb vertically overlapping the peripheral region PR.

The second structure ST2c may include a first peripheral circuit pTRa vertically overlapping the memory region CR and a second peripheral circuit pTRb vertically overlapping the peripheral region PR. The second structure ST2c may include a substrate 603 and a device isolation region 606 defining active regions 609 below the substrate 603. The substrate 603 may be configured as a semiconductor substrate.

The first and second peripheral circuits pTRa and pTRb may be disposed below the substrate 603.

Each of the first and second peripheral circuits pTRa and pTRb may include peripheral gate structures pGO and pGE disposed below the active region 609, peripheral source/drain regions pSD disposed in the active region 609 disposed on both sides of the peripheral gate structures pGO and pGE, and a peripheral channel region pCH between the peripheral source/drain regions pSD. The peripheral gate structure pGO and pGE may include a peripheral gate dielectric layer pGO and a peripheral gate electrode pGE, stacked in order in the downward direction.

The second structure ST2c may include a lower routing wiring structure 620 disposed below the substrate 603 and electrically connected to the first and second peripheral circuits pTRa and pTRb, a lower insulating structure 615 covering the lower routing wiring structure 620, and a second bonding pads 699 having a lower surface coplanar with a lower surface of the lower insulating structure 615. The second bonding pads 699 may be bonded to the first bonding pads 625, and the lower insulating structure 615 may be bonded to the insulating layer 662.

The lower routing wiring structure 620 may include a first lower routing wiring structure 620a and a second lower routing wiring structure 620b.

The second structure ST2c may further include an insulating layer 630 on the substrate 603, an input/output pad 650 on the insulating layer 603, a conductive through-via 640 electrically connecting the input/output pad 650 to the second lower routing wiring structure 620b between the input/output pad 650 and the second lower routing wiring structure 620b, and an insulating spacer 635 on a side surface of the conductive through-via 640. The conductive through-via 640 may penetrate the insulating layer 630 and the substrate 603.

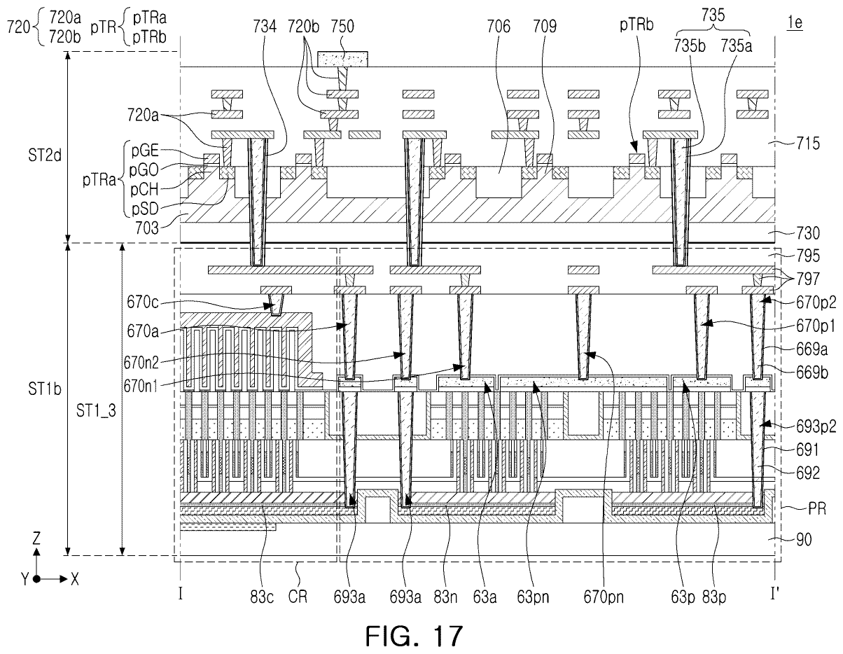

Referring to FIGS. 1 and 17, the first bonding pads 625 in the first structure ST1b in FIG. 16A may not be provided. The second structure ST2c in FIG. 16 may be replaced with the second structure ST2d in FIG. 17.

The second structure ST2d may include a first peripheral circuit pTRa vertically overlapping the memory region CR and a second peripheral circuit pTRb vertically overlapping the peripheral region PR.

The second structure ST2d may include a first peripheral circuit pTRa vertically overlapping the memory region CR and a second peripheral circuit pTRb vertically overlapping the peripheral region PR. The second structure ST2d may include a substrate 703 and a device isolation region 706 defining active regions 709 on the substrate 703. The substrate 703 may be configured as a semiconductor substrate.

The first and second peripheral circuits pTRa and pTRb may be disposed on the substrate 703.

Each of the first and second peripheral circuits pTRa and pTRb may include peripheral gate structures pGO and pGE disposed on the active region 709, peripheral source/drain regions pSD disposed in the active region 709 disposed on both sides of the peripheral gate structures pGO and pGE, and a peripheral channel region pCH between the peripheral source/drain regions pSD. The peripheral gate structure pGO and pGE may include the peripheral gate dielectric layer pGO and the peripheral gate electrode pGE, stacked in order.

The second structure ST2d may further include a lower routing wiring structure 720 disposed on the substrate 703 and electrically connected to the first and second peripheral circuits pTRa and pTRb, and a lower insulating structure 715 covering the lower routing wiring structure 720.

The lower routing wiring structure 720 may include a first lower routing wiring structure 720a and a second lower routing wiring structure 720b.

The second structure ST2d may further include an input/output pad 750 disposed on the lower insulating structure 715 and electrically connected to the second lower routing wiring structure 720b, and an insulating layer 730 disposed between the substrate 703 and the first structure ST1b. The insulating layer 730 and the insulating layer 795 may be bonded to each other.

The first and second structures ST1b and ST2d may be electrically connected to the first lower routing wiring structure 720a and may extend downwardly, and may further include conductive through-vias 735 penetrating the substrate 703 and the insulating layer 730 and in contact with and connected to the routing wiring structure 797, and insulating spacers 734 on side surfaces of the conductive through-vias 735. The conductive through-vias 735 may include a conductive pillar 735b and a conductive liner layer 735a covering a side surface and a lower surface of the conductive pillar 735b.

Accordingly, a semiconductor device 1b including the first structure ST1b and the second structure ST2d may be provided.

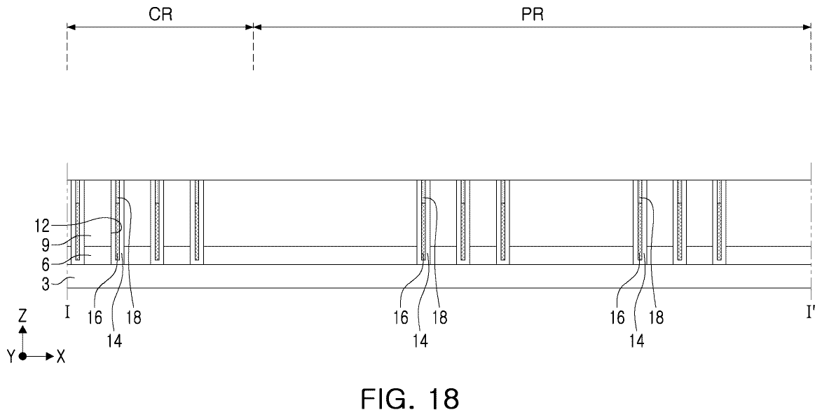

In the description below, an example of a method of manufacturing a semiconductor device according to some example embodiments will be described with reference to FIGS. 18 to 37. FIGS. 18 to 37 are cross-sectional diagrams illustrating regions taken along line I-I′ in FIG. 3, illustrating an example of the method of manufacturing a semiconductor device according to some example embodiments.

Referring to FIGS. 3 and 18, a sacrificial substrate 3, a sacrificial insulating layer 6, and a semiconductor layer 9, stacked in order, may be formed. The semiconductor layer 9 may be formed of a semiconductor material such as single crystal silicon.

Trenches 12 penetrating the semiconductor layer 9 and the sacrificial insulating layer 6 may be formed. The trenches 12 may be formed in a memory region CR and a peripheral region PR. Each of the trenches 12 may be configured as a line shape extending in the second horizontal direction Y. The semiconductor layer 9 may be spaced apart from each other in the first horizontal direction X by the trenches 12.

Forming a back gate dielectric layer 14 conformally covering internal walls of the trenches 12, forming a back gate conductive layer on the back gate dielectric layer 14, forming preliminary back gate electrodes 16 partially filling the trenches 12 by etching a portion of the back gate conductive layer using an etch back process, and forming back gate capping insulating layers 18 filling the other portions of the trenches 12 on the preliminary back gate electrodes 16 may be included. The back gate capping insulating layers 18 may be formed of an insulating material.

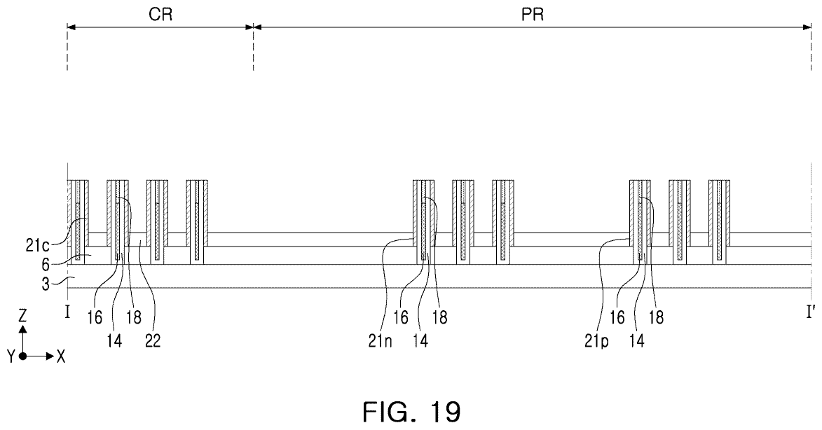

Referring to FIGS. 3 and 19, the vertical active patterns 21c, 21n, and 21p may be formed by patterning the semiconductor layers (9 in FIG. 18), and simultaneously, the sacrificial insulating layer 6 may be exposed.

The vertical active patterns 21c, 21n, and 21p may include cell vertical active patterns 21c formed in the memory region CR, and first peripheral active patterns 21n and second peripheral active patterns 21p formed in the peripheral region PR.

Among the vertical active patterns 21c, 21n, and 21c, a pair of vertical active patterns adjacent to each other may be formed on both sides of one of the preliminary back gate electrodes 16.

An insulating layer 22 may be formed on the exposed sacrificial insulating layer 6. An upper surface of the insulating layer 22 may be disposed on a level lower than a level of upper surfaces of the preliminary back gate electrodes 16.

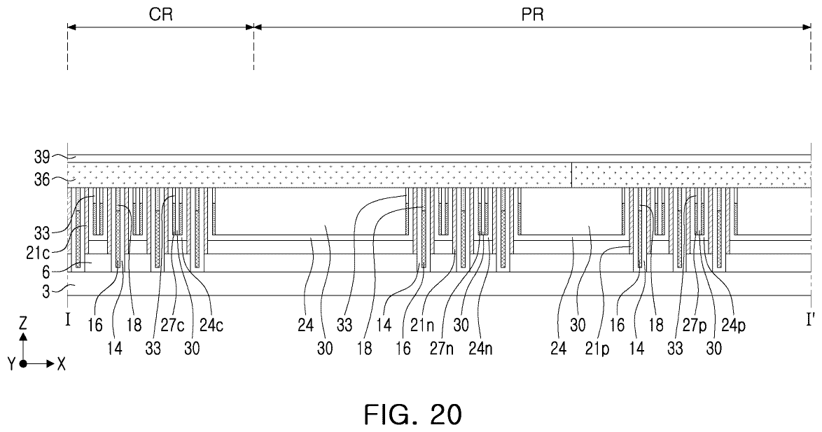

Referring to FIGS. 3 and 20, dielectric layers 24c, 24, 24n, and 24p and gate electrodes 27c, 27n, and 27p may be formed. The forming the dielectric layers 24c, 24, 24n, and 24p and the gate electrodes 27c, 27n, and 27p may include forming the dielectric layers 24c, 24, 24n, and 24p conformally covering the exposed upper surfaces of the insulating layer 22 and the side surfaces of the vertical active patterns 21c, 21n, and 21p, forming a preliminary gate conductive layer conformally coverings the gate dielectric layer 24c, 24, 24n, and 24p, forming gate conductive layers by anisotropically etching the preliminary gate conductive layer, forming isolation insulating layers 30 on the dielectric layers 24c, 24, 24n, and 24p, forming gate electrodes 27c, 27n, and 27p by etching a portion of the gate conductive layers, and forming gate capping insulating layers 33 on the gate electrodes 27c, 27n, and 27p.

The dielectric layers 24c, 24, 24n, and 24p may include cell gate dielectric layers 24c, first peripheral gate dielectric layers 24n, second peripheral gate dielectric layers 24p, and a dielectric layer 24. The cell gate dielectric layers 24c may be in contact with side surfaces of the cell vertical active patterns 21c. The first peripheral gate dielectric layers 24n may be in contact with side surfaces of the first peripheral vertical active patterns 21n. The second peripheral gate dielectric layers 24p may be in contact with side surfaces of the second peripheral vertical active patterns 21p. The dielectric layer 24 may be disposed between groups adjacent to each other among a group of the cell vertical active patterns 21c, a group of the first peripheral vertical active patterns 21n, and a group of the second peripheral vertical active patterns 21p.

The isolation insulating layers 30 may be disposed between the cell gate electrodes 27c adjacent to each other, between the first peripheral gate electrodes 27n adjacent to each other, between the second peripheral gate electrodes 27p adjacent to each other, and on the dielectric layer 24.

Upper surfaces of the vertical active patterns 21c, 21n, and 21p, the isolation insulating layers 30, and the gate capping insulating layers 33 may be coplanar with each other.

Thereafter, the first semiconductor layer 36 and the protective layer 39 on the first semiconductor layer 36 may be formed. A lower surface of the first semiconductor layer 36 may be in contact with upper surfaces of the vertical active patterns 21c, 21n, and 21p.

The vertical active patterns 21c, 21n, and 21p may be formed of single crystal silicon. For example, the vertical active patterns 21c, 21n, and 21p may be formed from undoped single crystal silicon.

In some example embodiments, the first semiconductor layer 36 may be formed of polysilicon. For example, the first semiconductor layer 36 may be formed of undoped polysilicon.

In some example embodiments, the first semiconductor layer 36 may be formed of epitaxial silicon.

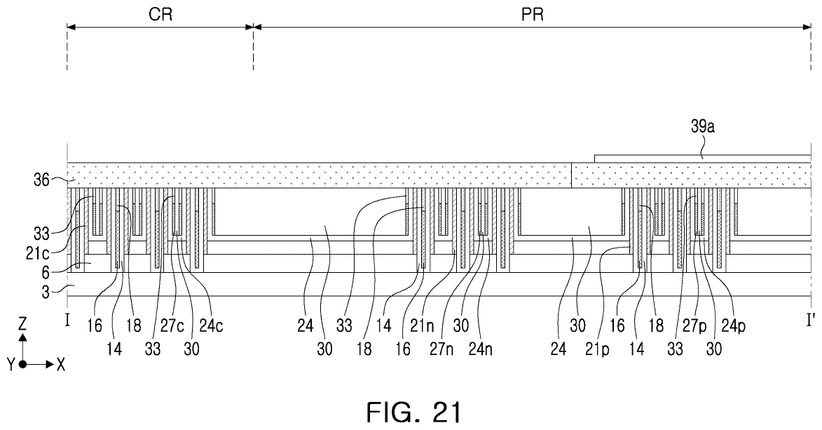

Referring to FIGS. 3 and 21, by patterning the protective layer (39 in FIG. 20), a portion of the first semiconductor layer 36 in contact with the cell vertical active patterns 21c and the first peripheral active patterns 21n may be exposed, and a lower protective pattern 39a remaining on the portion of the first semiconductor layer 36 in contact with the second peripheral active patterns 21p may be formed.

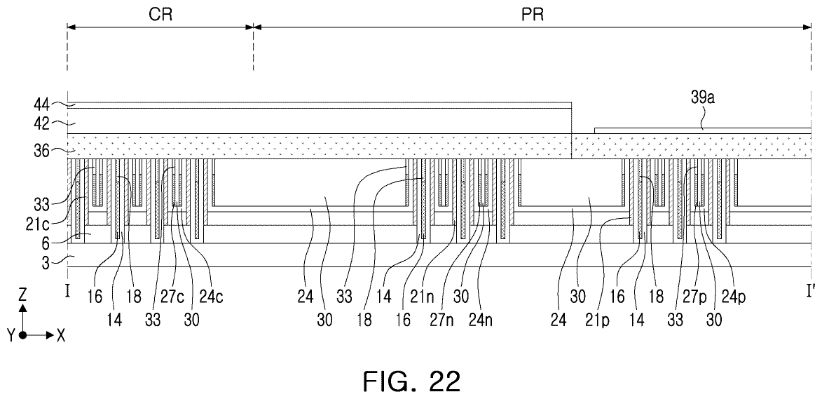

Referring to FIGS. 3 and 22, a second semiconductor layer 42 and an upper protective pattern 44 may be formed stacked in order on the first semiconductor layer 36 exposed by the protective pattern 39a. The second semiconductor layer 42 may be formed of polysilicon having N-type conductivity.

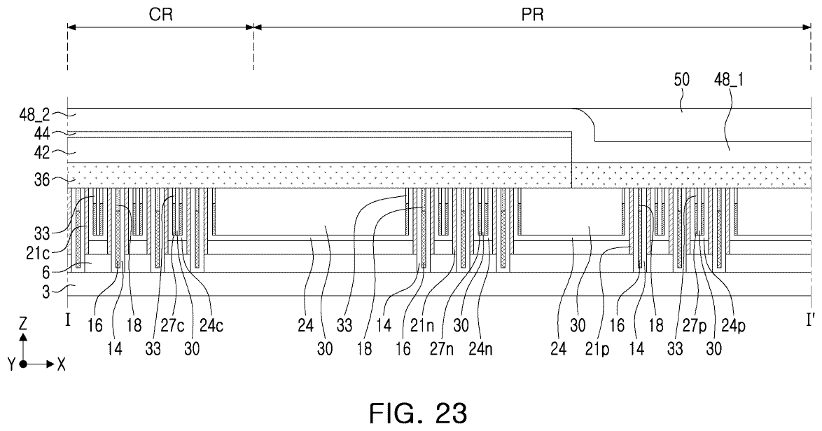

Referring to FIGS. 3 and 23, the lower protective pattern (39a in FIG. 22) may be removed. Accordingly, a portion of the first semiconductor layer 36 in contact with the second peripheral active patterns 21p may be exposed.

Third semiconductor layers 48_1 and 48_2 may be formed. The third semiconductor layers 48_1 and 48_2 may include a first portion 48_1 in contact with an upper surface of the first semiconductor layer 36 which is in contact with the second peripheral active patterns 21p, and a second portion 48_2 in contact with an upper surface of the upper protective pattern 44. The second portion 48_2 may be formed on a level higher than a level of the first portion 48_1. The third semiconductor layers 48_1 and 482 may be formed of polysilicon having P-type conductivity. An insulating layer may be formed on the third semiconductor layer 48_1 and 48_2, and the insulating layer may be planarized until the upper surface of the second portion 48_2 is exposed, thereby forming a buffer insulating pattern 50 remaining on the first portion 48_1.

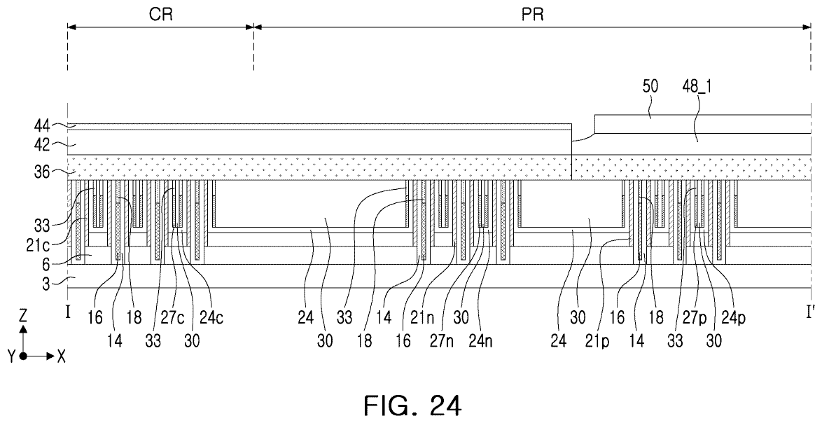

Referring to FIGS. 3 and 24, the second portion 48_2 of the third semiconductor layer 48_1 and 48_2 may be removed by etching. Accordingly, the first portion 48_1 of the third semiconductor layer 48_1 and 48_2 may remain.

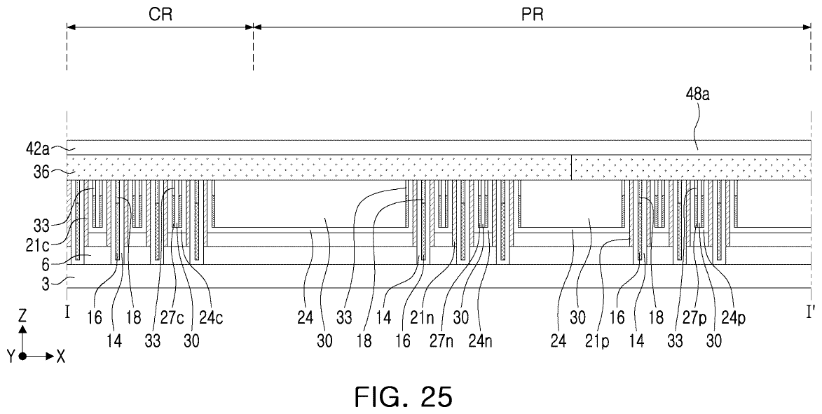

Referring to FIGS. 3 and 25, the third semiconductor pattern 48a and the second semiconductor pattern 42a may be formed by planarizing a thickness of the first portion 48_1 of the third semiconductor layers 48_1 and 48_2 and the second semiconductor layer 42. During the planarization, the upper protective pattern 44 and the buffer insulating pattern 50 may be removed.

The third semiconductor pattern 48a and the second semiconductor pattern 42a may have substantially the same thickness.

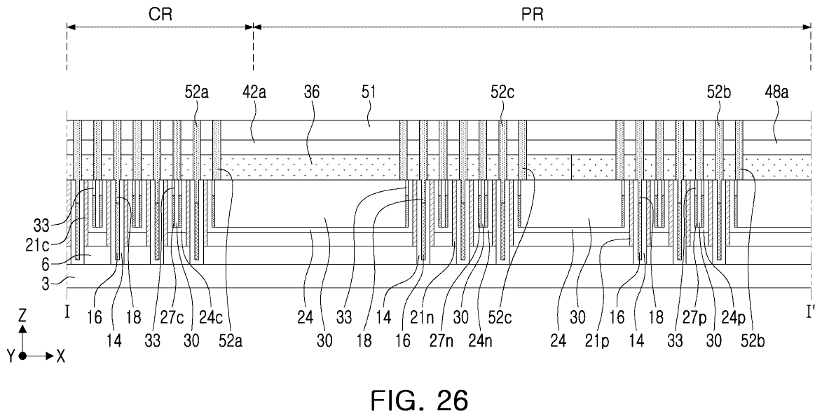

Referring to FIGS. 3 and 26, an insulating layer 51 may be formed on the third semiconductor pattern 48a and the second semiconductor pattern 42a.

Isolation patterns 52a, 52b, and 52c may be formed. The isolation patterns 52a, 52b, and 52c may be formed of an insulating material different from a material of the insulating layer 51. For example, the insulating layer 51 may be formed of an insulating oxide, such as silicon oxide, and the isolation patterns 52a, 52b, and 52c may be formed of an insulating nitride, such as silicon nitride.

The isolation patterns 52a, 52b, and 52c may include cell isolation patterns 52a, first peripheral isolation patterns 52c, and second peripheral isolation patterns 52b. The isolation patterns 52a, 52b, and 52c may be spaced apart from the vertical active patterns 21c, 21n, and 21p.

The cell isolation patterns 52a may be formed in the memory region CR and may penetrate the insulating layer 51, the second semiconductor pattern 42a and the first semiconductor layer 36. The first peripheral isolation patterns 52c may be formed in the peripheral region PR and may penetrate the insulating layer 51, the second semiconductor pattern 42a and the first semiconductor layer 36. The second peripheral isolation patterns 52b may be formed in the peripheral region PR and may penetrate the insulating layer 51, the third semiconductor pattern 48a and the first semiconductor layer 36.

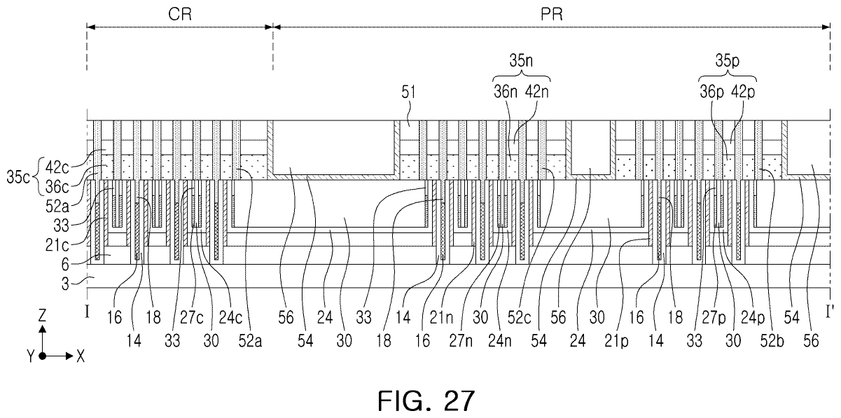

Referring to FIGS. 3 and 27, insulating structures 54 and 56 may be formed. Each of the insulating structures 54 and 56 may be disposed between groups adjacent to each other among a group of the cell isolation patterns 52a, a group of the first peripheral isolation patterns 52c, and a group of the second peripheral isolation patterns 52b.

The insulating structures 54 and 56 may penetrate the insulating layer 51 and the second and third semiconductor patterns 42a and 48a. Each of the insulating structures 54 and 56 may include an insulating pattern 56 and an insulating liner 54 covering a side surface and a lower surface of the insulating pattern 56. The insulating pattern 56 may include an oxide, and the insulating liner 54 may include a nitride.

First impurities in the second semiconductor pattern (42a in FIG. 26) may diffuse into the first semiconductor layer (36 in FIG. 26), upper regions of the cell vertical active pattern 21c and the first peripheral vertical active pattern 21n. Accordingly, a concentration of first impurities in the second semiconductor pattern (42a in FIG. 26) may be higher than a concentration of first impurities in the first semiconductor layer (36 in FIG. 26), and a concentration of first impurities in the first semiconductor layer (36 in FIG. 26) may be higher than a concentration of first impurities in an upper region of the cell vertical active pattern 21c and an upper region of the first peripheral vertical active pattern 21n. The first impurities may be a group V element in the periodic table, for example P or As.

The second impurities in the third semiconductor pattern (48a in FIG. 26) may diffuse into the first semiconductor layer (36 in FIG. 26) and upper region of the second peripheral vertical active pattern 21p. Accordingly, a concentration of second impurities in the third semiconductor pattern (48a in FIG. 26) may be higher than a concentration of second impurities in the first semiconductor layer (36 in FIG. 26), and a concentration of second impurities in the first semiconductor layer (36 in FIG. 26) may be higher than a concentration of second impurities in an upper region of the second peripheral vertical active pattern 21p. The second impurities may be configured as a group III element in the periodic table, for example B or A1. The first semiconductor layer (36 in FIG. 26) may be formed of polysilicon doped with group V elements and group III elements.

The first semiconductor layer (36 in FIG. 26) and the second semiconductor pattern (42a in FIG. 26) defined by the cell isolation patterns 52a may be formed as first cell upper source/drain patterns 36c and second cell upper source/drain patterns 42c. The first semiconductor layer (36 in FIG. 26) and the second semiconductor pattern (42a in FIG. 26) defined by the first peripheral isolation patterns 52c may be formed as first-1 peripheral upper source/drain patterns 36n and first-2 peripheral upper source/drain patterns 42n. The first semiconductor layer (36 in FIG. 26) and the third semiconductor pattern (48a in FIG. 26) defined by the second peripheral isolation patterns 52b may be formed as second-1 peripheral upper source/drain patterns 36p and second-2 peripheral upper source/drain patterns 42p.

The first cell upper source/drain pattern 36c and the second cell upper source/drain pattern 42c, stacked in order, may be included in a cell upper source/drain pattern 35c. The first-1 peripheral upper source/drain pattern 36n and the first-2 peripheral upper source/drain pattern 42n, stacked in order, may be included in the first peripheral upper source/drain pattern 35n. The second-1 peripheral upper source/drain pattern 36p and the second-2 peripheral upper source/drain pattern 42p, stacked in order, may be included in the second peripheral upper source/drain pattern 35p.

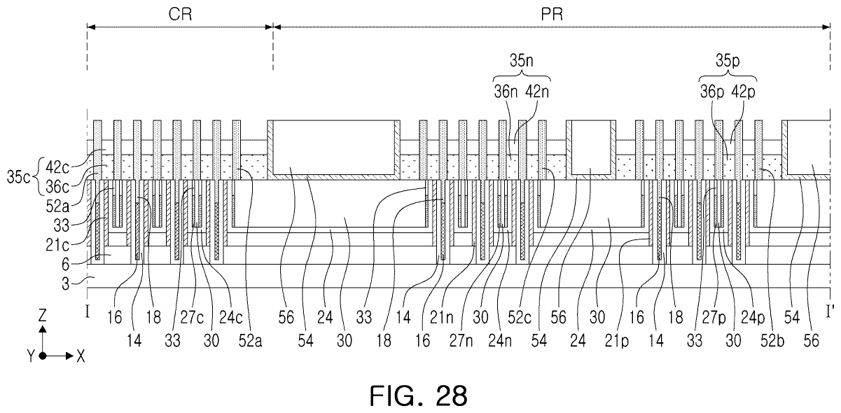

Referring to FIGS. 3 and 28, the insulating layer (51 in FIG. 27) may be removed. Accordingly, upper surfaces of the second cell upper source/drain patterns 42c, upper surfaces of the first-2 peripheral upper source/drain patterns 42n, upper surfaces of the second-2 peripheral upper source/drain patterns 42p, upper side surfaces and upper surfaces of the insulating structures 54 and 56, and upper side surfaces and upper surfaces of the isolation patterns 52a, 52b, and 52c may be exposed.

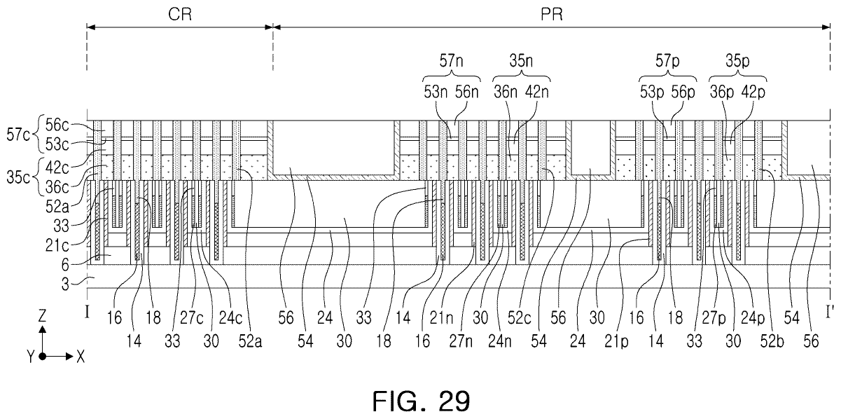

Referring to FIGS. 3 and 29, contact plugs 57c, 57n, and 57p may be formed. The contact plugs 57c, 57n, and 57p may include cell contact plugs 57c formed on upper surfaces of the second cell upper source/drain patterns 42c, first peripheral contact plugs 57n formed on upper surfaces of the first-2 peripheral upper source/drain patterns 42n, and second peripheral contact plugs 57p formed on upper surfaces of the second-2 peripheral upper source/drain patterns 42p.

Each of the cell contact plugs 57c may include a metal-semiconductor compound layer 53c in contact with an upper surface of the second cell upper source/drain pattern 42c and a plug pattern 56c on the metal-semiconductor compound layer 53c. Each of the first peripheral contact plugs 57n may include a metal-semiconductor compound layer 53n in contact with an upper surface of the first-2 peripheral upper source/drain pattern 42n and a plug pattern 56n on the metal-semiconductor compound layer 53n. Each of the second peripheral contact plugs 57p may include a metal-semiconductor compound layer 53p in contact with an upper surface of the second-2 peripheral upper source/drain pattern 42p and a plug pattern 56p on the metal-semiconductor compound layer 53p.

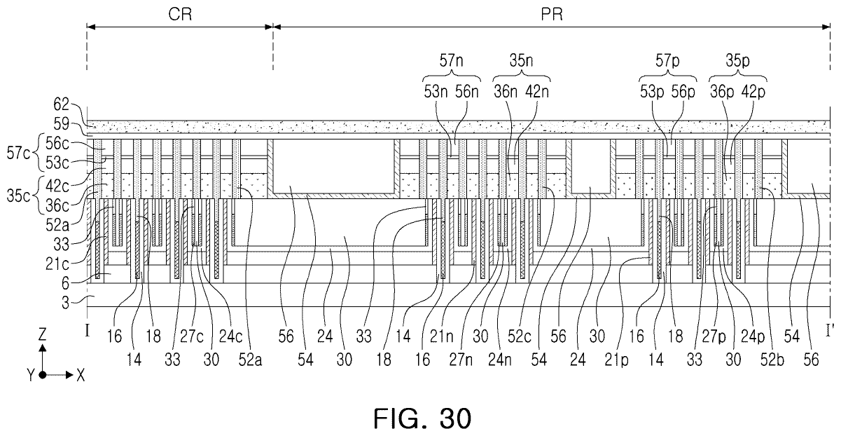

Referring to FIGS. 3 and 30, conductive structures 59 and 62 may be formed on the contact plugs 57c, 57n, and 57p, the insulating structures 54 and 56, and the isolation patterns 52a, 52b, and 52c. The conductive structures 59 and 62 may include a first conductive layer 59 and a second conductive layer 62 stacked in that order.

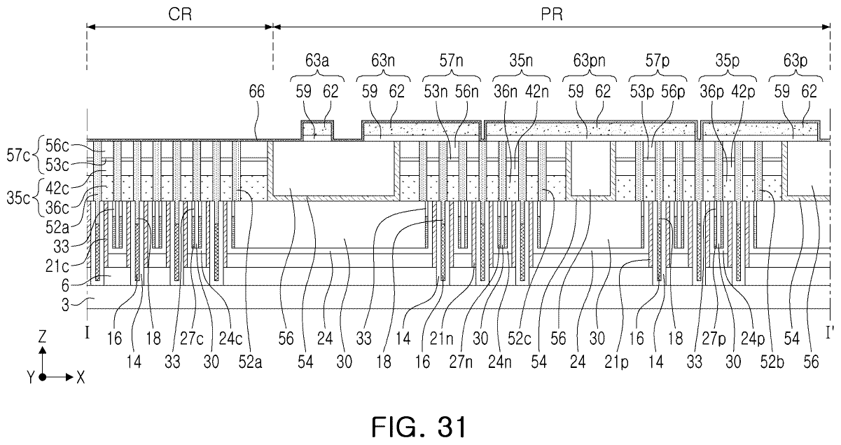

Referring to FIGS. 3 and 31, conductive patterns 63a, 63n, 63pn, and 63p may be formed by patterning the conductive structures 59 and 62. The conductive patterns 63a, 63n, 63pn and 63p may include a pad pattern 63a, a first upper wiring 63n, a second upper wiring 63p, and an upper connection wiring 63pn.

The first upper wiring 63n may be connected to a portion of the first peripheral contact plugs 57n. The second upper wiring 63p may be connected to a portion of the second peripheral contact plugs 57p. The upper connection wiring 63pn may electrically connect a portion of the first peripheral contact plugs 57n to a portion of the second peripheral contact plugs 57p. The pad pattern 63a may be disposed on the insulating structures 54 and 56.

An insulating liner 66 covering upper surfaces and side surfaces of the conductive patterns 63a, 63n, 63pn, and 63p in the peripheral region PR, and upper surfaces of the cell contact plugs 57c and the cell isolation pattern 52a in the memory region CR may be formed.

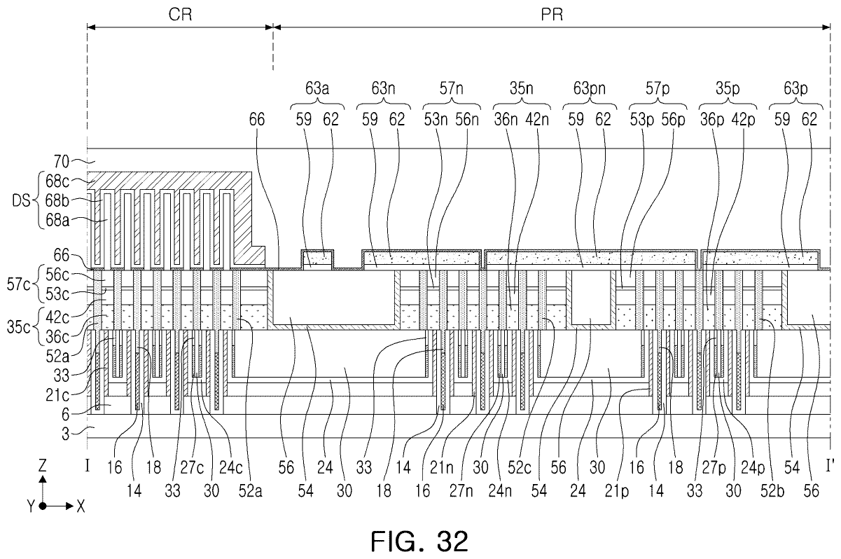

Referring to FIGS. 3 and 32, a data storage structure DS may be formed. The data storage structure DS may include first electrodes 68a connected to the cell plug patterns 57c, penetrating the insulating liner 66, and extending in the vertical direction Z, a second electrode 68c on each of side surfaces and upper surfaces of the first electrodes 68a, and a dielectric layer 68b between the first electrodes 68a and the second electrode 68c.

An insulating layer 70 covering the data storage structure DS in the memory region CR and the insulating liner 66 in the peripheral region PR may be formed. The insulating liner 66 may include a material different from a material of the insulating layer 70.

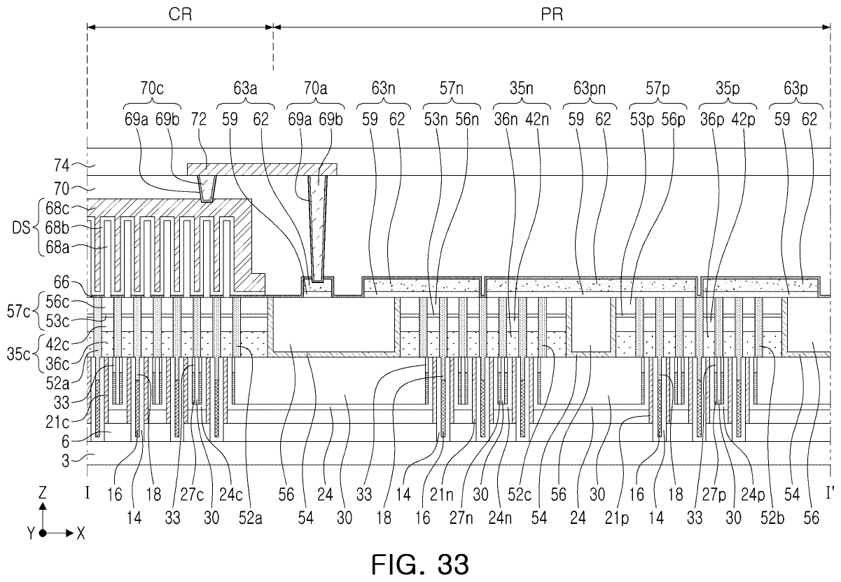

Referring to FIGS. 3 and 33, contact plugs 70a and 70c may be formed. Each of the contact plugs 70a may include a conductive plug pattern 69b and a conductive liner 69a covering a side surface and a lower surface of the conductive plug pattern 69b.

The contact plugs 70a and 70c may include a cell contact plug 70c penetrating the insulating layer 70 and connected to the second electrode 68c, and a connection contact plug 70a penetrating the insulating layer 70 and the insulating liner 66 and connected to the pad pattern 63a.

Upper wiring 72 connected to the contact plugs 70a and 70c may be formed on the contact plugs 70a and 70c and the insulating layer 70. An insulating layer 74 may be formed on the insulating layer 70 and the upper wiring 72.

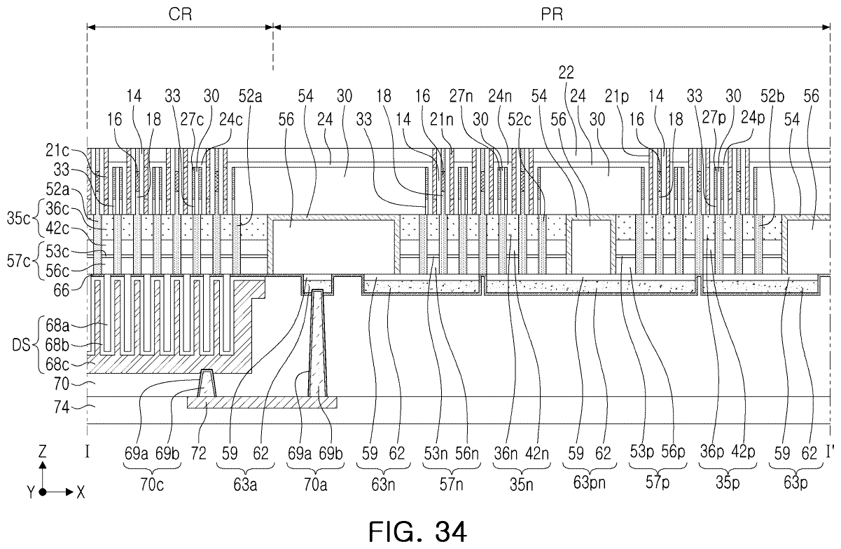

Referring to FIGS. 3 and 34, the insulating layer 74 may be disposed in the downward direction, and the sacrificial substrate 3 and the sacrificial insulating layer 6 may be removed. Back gate electrodes 16c, 16n, and 16p may be formed by etching the preliminary back gate electrodes 16, and insulating layers 75 may be formed on the back gate electrodes 16c, 16n, and 16p. The insulating layer 22 and the vertical active patterns 21c, 21n, and 21p may be exposed.

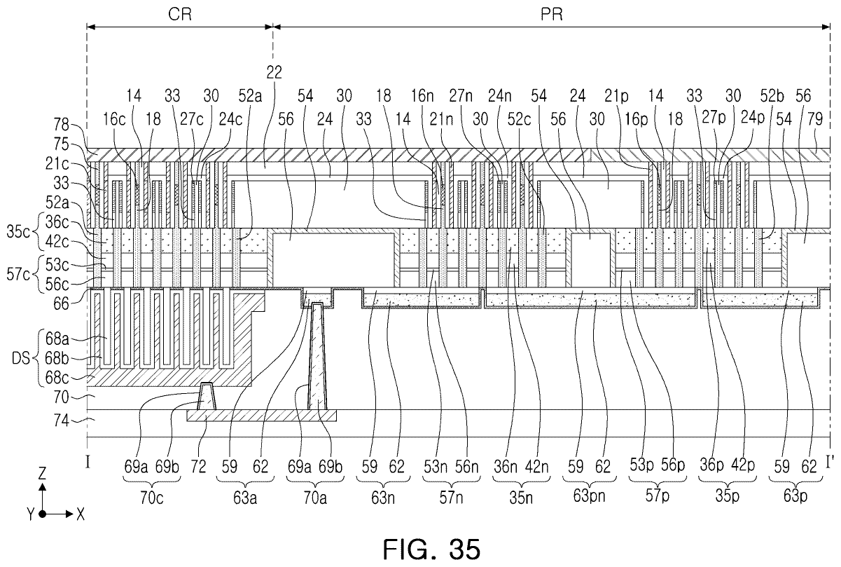

Referring to FIGS. 3 and 35, a fifth semiconductor pattern 78 and a sixth semiconductor pattern 79 corresponding to the second semiconductor pattern (42a in FIG. 25) and the third semiconductor pattern (48a in FIG. 25) may be formed on the exposed insulating layer 22 and the exposed vertical active patterns 21c, 21n, and 21p. The fifth semiconductor pattern 78 and the sixth semiconductor pattern 79 may be formed in the same manner as the second semiconductor pattern (42a in FIG. 25) and the third semiconductor pattern (48a in FIG. 25). Accordingly, the second semiconductor pattern (42a in FIG. 25) and the fifth semiconductor pattern 78 may be formed of the same material, and the third semiconductor pattern (48a in FIG. 25) and the sixth semiconductor pattern 79 may be formed of the same material.

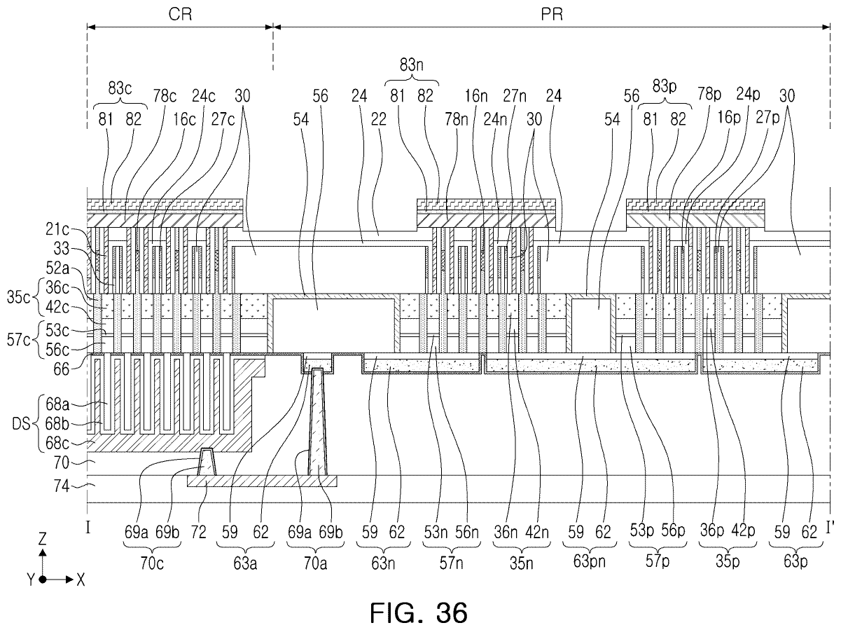

Referring to FIGS. 3 and 36, conductive structures 81 and 82 may be formed on the fifth semiconductor pattern 78 and the sixth semiconductor pattern 79. The conductive structures 81 and 82 may include a first conductive layer 81 and a second conductive layer 82 stacked in order.

By patterning the conductive structure 81 and 82, the fifth semiconductor pattern 78 and the sixth semiconductor pattern 79, conductive patterns 83c, 83n, and 83p and lower source/drain patterns 78c, 78n, and 78p may be formed.

The lower source/drain patterns 78c, 78n, and 78p may include a cell lower source/drain pattern 78c connected to the cell vertical active patterns 21c, a first peripheral lower source/drain pattern 78n connected to the first peripheral vertical active patterns 21n, and a second peripheral lower source/drain pattern 78p connected to the first peripheral vertical active patterns 21p.

Impurities in the cell lower source/drain pattern 78c may diffuse into the cell vertical active patterns 21c, such that source/drain regions may be formed in the cell vertical active patterns 21c. Impurities in the first peripheral lower source/drain pattern 78n may diffuse into the first peripheral vertical active patterns 21n, such that source/drain regions may be formed in the first peripheral vertical active patterns 21n. Impurities in the second peripheral lower source/drain pattern 78p may diffuse into the second peripheral vertical active patterns 21p, such that source/drain regions may be formed in the second peripheral vertical active patterns 21p.

The conductive patterns 83c, 83n, and 83p may include a bit line 83c in contact with the cell lower source/drain pattern 78c and self-aligned, a first lower wiring 83n in contact with the first peripheral lower source/drain pattern 78n and self-aligned, and a second lower wiring 83p in contact with the second peripheral lower source/drain pattern 78p and self-aligned.

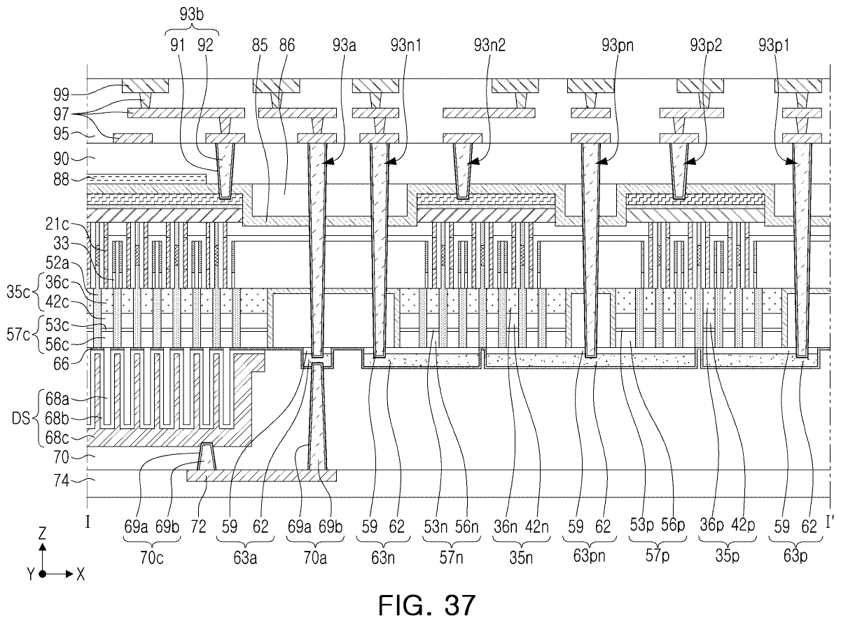

Referring to FIGS. 3 and 37, insulating structures 85 and 86 and bit line shield structure 88 may be formed. The insulating structures 85 and 86 may include an insulating pattern 86 and an insulating liner 85 covering an upper surface of the insulating pattern 86, side surfaces of the lower source/drain patterns 78c, 78n, and 78p, and side surfaces and lower surfaces of the conductive patterns 83c, 83n, and 83p. The bit line shield structure 88 may be disposed between the bit lines 83c and may be disposed below the bit lines 83c. The bit line shield structure 88 may be spaced apart from the bit lines 83c by the insulating liner 85.

An insulating layer 90 may be formed on the insulating structures 85 and 86 and the bit line shield structure 88.

Contact plugs 93b, 93a, 93n1, 93n2, 93pn, 93p2, and 93p1 penetrating the insulating layer 90 and extending downward may be formed.

Each of the contact plugs 93b, 93a, 93n1, 93n2, 93pn, 93p2, and 93p1 may include a conductive plug pattern 92 and a conductive liner 91 covering a lower surface and a side surface of the conductive plug pattern 92. The contact plugs 93b, 93a, 93n1, 93n2, 93pn, 93p2, and 93p1 may include a contact plug 93b connected to and in contact with the bit line 83c, a contact plug 93a connected to and in contact with the pad pattern 63a, a contact plug 93n1 connected to and in contact with the first upper wiring 63n, a contact plug 93n2 connected to and in contact with the first lower wiring 83n, a contact plug 93pn connected to and in contact with the upper connection wiring 63pn, a contact plug 93p2 connected to and in contact with the second lower wiring 83p, and a contact plug 93p1 connected to and in contact with the second upper wiring 63p.

An insulating structure 95 formed on the contact plugs 93b, 93a, 93n1, 93n2, 93pn, 93p2, and 93p1 and the insulating layer 90, a routing wiring structure 97 disposed in the insulating structure 95 and electrically connected to the contact plugs 93b, 93a, 93n1, 93n2, 93pn, 93p2, and 93p1, and bonding pads 99 connected to the routing wiring structure 97 may be formed. An upper surface of the insulating structure 95 and upper surfaces of the bonding pads 99 may be coplanar with each other. Accordingly, the first structure ST1a as illustrated in FIG. 14A may be formed.

According to the aforementioned example embodiments, a transistor may include a lower source/drain, a vertical channel region and an upper source/drain vertically arranged. The upper source/drain may include an upper source/drain region disposed in an upper region of the vertical active pattern and an upper source/drain pattern disposed on the vertical active pattern. The lower source/drain may include a lower source/drain region disposed in a lower region of the vertical active pattern and a lower source/drain pattern disposed below the vertical active pattern. Each of the lower and upper source/drain patterns may improve leakage current properties of the transistor. By including the lower and upper source/drain patterns in the transistor, performance of the transistor may be improved.

Also, an upper contact plug vertically aligned with the upper source/drain and a lower wiring vertically aligned with the lower source/drain may be provided.

Also, an upper wiring on the upper contact plug and an insulating liner covering the upper wiring may be provided.

Accordingly, by including the transistor, the upper contact plug, the upper wiring, the lower wiring, and the insulating liner, performance and integration density may be improved.

While some example embodiments have been illustrated and described above, it will be configured as apparent to those skilled in the art that modifications and variations may be made without departing from the scope in the example embodiments as defined by the appended claims.

What is claimed is:

1. A semiconductor device, comprising:
a memory region and a peripheral region,
the memory region including,
a cell vertical active pattern;
a cell gate electrode having a side surface facing a side surface of the cell vertical active pattern;
a cell upper source/drain pattern and a cell contact plug sequentially stacked on the cell vertical active pattern;
a cell isolation pattern on side surfaces of the cell upper source/drain pattern and the cell contact plug; and
a data storage structure on the cell contact plug and the cell isolation pattern, the peripheral region including,
a peripheral vertical active pattern;
a peripheral gate electrode having a side surface facing a side surface of the peripheral vertical active pattern;
a peripheral upper source/drain pattern and a peripheral contact plug sequentially stacked on the peripheral vertical active pattern;
a peripheral isolation pattern on a side surface of the peripheral upper source/drain pattern and a side surface of the peripheral contact plug; and
an upper wiring on the peripheral contact plug and the peripheral isolation pattern,
wherein the cell upper source/drain pattern includes a first cell upper source/drain pattern and a second cell upper source/drain pattern on the first cell upper source/drain pattern, and
wherein the peripheral upper source/drain pattern includes a first peripheral upper source/drain pattern and a second peripheral upper source/drain pattern on the first peripheral upper source/drain pattern.

2. The semiconductor device of claim 1, wherein the second peripheral upper source/drain pattern has a concentration of impurities higher than a concentration of impurities of the first peripheral upper source/drain pattern.

3. The semiconductor device of claim 2,
wherein the peripheral vertical active pattern includes,
a peripheral lower source/drain region;
a peripheral vertical channel region on the peripheral lower source/drain region; and
a peripheral upper source/drain region on the peripheral vertical channel region,
wherein the peripheral upper source/drain pattern is in contact with the peripheral upper source/drain region of the peripheral vertical active pattern.

4. The semiconductor device of claim 3, wherein the second peripheral upper source/drain pattern has a concentration of impurities higher than a concentration of impurities of the peripheral upper source/drain region.

5. The semiconductor device of claim 1,
wherein the cell vertical active pattern includes first single crystal silicon,
wherein the peripheral vertical active pattern includes second single crystal silicon,
wherein the cell upper source/drain pattern includes first polysilicon, and
wherein the peripheral upper source/drain pattern includes second polysilicon.

6. The semiconductor device of claim 1, wherein each of the cell contact plug and the peripheral contact plug is a single conductive layer.

7. The semiconductor device of claim 1, wherein each of the cell contact plug and the peripheral contact plug includes a plug pattern and a barrier layer covering a lower surface and a side surface of the plug pattern.

8. The semiconductor device of claim 1, wherein the memory region and the peripheral region further include an insulating liner on the cell contact plug, the cell isolation pattern, and the upper wiring.

9. The semiconductor device of claim 8, wherein the insulating liner covers an upper surface and a side surface of the upper wiring.

10. The semiconductor device of claim 8, wherein the data storage structure includes:
a first electrode in contact with the cell contact plug, the first electrode penetrating the insulating liner, and extending upwardly;
a dielectric layer on the first electrode and the insulating liner; and
a second electrode on the dielectric layer.

11. The semiconductor device of claim 8, further comprising:
a buffer insulating layer between the insulating liner and the upper wiring.

12. The semiconductor device of claim 1,
wherein the memory region further includes,
a cell lower source/drain pattern below the cell vertical active pattern; and
a bit line below the cell lower source/drain pattern, and
wherein the peripheral region further includes,
a peripheral lower source/drain pattern below the peripheral vertical active pattern; and
a lower wiring below the peripheral lower source/drain pattern.

13. A semiconductor device, comprising:
a cell vertical active pattern and a peripheral vertical active pattern spaced apart from each other;
a cell upper source/drain pattern and a cell contact plug sequentially stacked on the cell vertical active pattern and self-aligned;
a peripheral upper source/drain pattern and a peripheral contact plug sequentially stacked on the peripheral vertical active pattern and self-aligned;
a cell isolation pattern on a side surface of the cell upper source/drain pattern and a side surface of the cell contact plug;
a peripheral isolation pattern on a side surface of the peripheral upper source/drain pattern and a side surface of the peripheral contact plug;
an upper wiring connected to the peripheral contact plug and on the peripheral contact plug;
an insulating liner on the cell contact plug, the cell isolation pattern, and the upper wiring; and
a data storage structure including
a first electrode connected to the cell contact plug, the first electrode penetrating the insulating liner and extending upwardly,
a dielectric layer on the first electrode, and
a second electrode on the dielectric layer,
wherein the insulating liner includes a first portion on an upper surface of the cell isolation pattern and a second portion on an upper surface of the upper wiring, and
wherein the second portion of the insulating liner is at a higher level than the first portion of the insulating liner.

14. The semiconductor device of claim 13, wherein the insulating liner covers an upper surface and a side surface of the upper wiring.

15. The semiconductor device of claim 13, further comprising:
a cell lower source/drain pattern below the cell vertical active pattern;
a bit line below the cell lower source/drain pattern;
a peripheral lower source/drain pattern below the peripheral vertical active pattern; and
a lower wiring below the peripheral lower source/drain pattern,
wherein the cell upper source/drain pattern includes a first cell upper source/drain pattern and a second cell upper source/drain pattern on the first cell upper source/drain pattern, and
wherein the peripheral upper source/drain pattern includes a first peripheral upper source/drain pattern and a second peripheral upper source/drain pattern on the first peripheral upper source/drain pattern.

16. A semiconductor device, comprising:
a first structure including a memory region and a peripheral region; and
a second structure vertically overlapping the first structure and including a peripheral circuit,
wherein the memory region includes,
a cell vertical active pattern;
a cell gate electrode having a side surface facing a side surface of the cell vertical active pattern;
a cell upper source/drain pattern and a cell contact plug sequentially stacked on the cell vertical active pattern;
a cell isolation pattern on side surfaces of the cell upper source/drain pattern and the cell contact plug; and
a data storage structure on the cell contact plug and the cell isolation pattern,
wherein the peripheral region includes,
a first peripheral vertical active pattern;
a first peripheral gate electrode having a side surface facing a side surface of the first peripheral vertical active pattern;
a first peripheral upper source/drain pattern and a first peripheral contact plug sequentially stacked on the first peripheral vertical active pattern;
a peripheral isolation pattern on a side surface of the first peripheral upper source/drain pattern and a side surface of the first peripheral contact plug; and
a first upper wiring on the first peripheral contact plug and the peripheral isolation pattern,
wherein the cell upper source/drain pattern includes a first cell upper source/drain pattern and a second cell upper source/drain pattern sequentially stacked,
wherein the first peripheral upper source/drain pattern includes a first-1 peripheral upper source/drain pattern and a first-2 peripheral upper source/drain pattern sequentially stacked,
wherein the memory region and the peripheral region further include an insulating liner on the cell contact plug, the cell isolation pattern, and the first upper wiring, and
wherein the peripheral circuit includes a first lower transistor vertically overlapping the memory region and a second lower transistor vertically overlapping the peripheral region.

17. The semiconductor device of claim 16,
wherein the cell vertical active pattern includes,
a cell lower source/drain region;
a cell vertical channel region on the cell lower source/drain region; and
a cell upper source/drain region on the cell vertical channel region,
wherein the cell upper source/drain pattern is in contact with the cell upper source/drain region of the cell vertical active pattern, and
wherein a side surface of the cell upper source/drain pattern and a side surface of the cell contact plug are aligned.

18. The semiconductor device of claim 16, wherein the insulating liner covers an upper surface and a side surface of the first upper wiring.

19. The semiconductor device of claim 16,
wherein the peripheral region includes,
a second peripheral vertical active pattern;
a second peripheral gate electrode having a side surface facing a side surface of the second peripheral vertical active pattern; and
a second peripheral upper source/drain pattern and a second peripheral contact plug sequentially stacked on the second peripheral vertical active pattern,
wherein the first upper wiring extends to the second peripheral contact plug and electrically connects the first and second peripheral contact plugs to each other.

20. The semiconductor device of claim 16,
wherein the peripheral region includes,
a second peripheral vertical active pattern;
a second peripheral gate electrode having a side surface facing a side surface of the second peripheral vertical active pattern;
a second peripheral upper source/drain pattern and a second peripheral contact plug sequentially stacked on the second peripheral vertical active pattern;
a second upper wiring on the second peripheral contact plug; and
an upper connection wiring structure connected to the first and second upper wirings,
wherein the upper connection wiring structure includes,
a wiring portion vertically overlapping the first and second upper wirings;
an interlayer insulating layer below the wiring portion;
a first via penetrating the interlayer insulating layer and connecting the first upper wiring to the wiring portion; and
a second via penetrating the interlayer insulating layer and connecting the second upper wiring to the wiring portion.
